(19) United States
(12) Patent Application Publication
(10) Pub. No.: US 2025/0316571 A1
(43) Pub. Date: Oct. 9, 2025

(54) SEMICONDUCTOR PACKAGE

(71) Applicant: LG INNOTEK CO., LTD., Seoul (KR)

(72) Inventors: Ho Dol YOO, Seoul (KR); Dong Keon LEE, Seoul (KR); Yu Lim CHOE, Seoul (KR)

(21) Appl. No.: 18/714,667

(22) PCT Filed: Nov. 30, 2022
(86) PCT No.: PCT/KR2022/019268

§ 371 Date: Oct. 15, 2024

(30) Foreign Application Priority Data
Nov. 30, 2021 (KR) 10-2021-0169522

(51) Int. Cl. H01L 23/498; H01L 23/00; H01L 23/538; H01L 25/16

(52) U.S. Cl. CPC H01L 23/49822; H01L 23/5383; H01L 23/562; H01L 25/16

(57) ABSTRACT

A semiconductor package according to an embodiment includes an insulating layer; a first electrode part disposed on the insulating layer; a through electrode passing through the insulating layer and electrically connected to the first electrode part; and a reinforcement part disposed in the insulating layer; a connection part disposed on the first electrode part; and a chip mounted on the connection part, and wherein at least a portion of the reinforcement part vertically overlaps the chip and is not connected to the through electrode.

### TECHNICAL FIELD

An embodiments relates to a semiconductor package, and more particularly, to a semiconductor package with improved warpage characteristics.

### BACKGROUND ART

As the performance of electric/electronic products progresses, technologies for attaching a larger number of packages to a substrate of a limited size have been proposed and researched. However, since general packages are based on mounting a single semiconductor chip, there is a limit to obtaining desired performance.

A general package substrate has a form in which a processor package in which a processor chip is disposed and a memory package to which the memory chip is attached are connected as one. Such a package substrate may have a structure in which a processor chip and a memory chip are integrated into one package, thereby reducing a mounting area of the chip and enabling high-speed signal transmission through a short pass.

Due to these advantages, the package substrate is widely applied to mobile devices, etc.

The package substrate as described above requires connection between a plurality of chips, and thus is being refined and slimmed down to arrange electrodes connected to a plurality of chips in a limited space.

The package substrate has a problem in that warpage characteristics are deteriorated due to miniaturization and slimming. In addition, when the warpage characteristics are deteriorated in a region vertically overlapping the chip among the entire region of the package, stress may be transmitted to the chip.

In addition, when stress is transmitted to the chip, physical and electrical reliability problems may occur in which the chip is separated from the package substrate due to the stress. In addition, the stress may affect the operability of the chip, and accordingly, there is a problem in that the operational characteristics of the chip are deteriorated.

### DISCLOSURE

### Technical Problem

The embodiment provides a semiconductor package having a new structure.

In addition, an embodiment provides a semiconductor package with improved warpage characteristics.

In addition, an embodiment provides a semiconductor package with improved physical and electrical reliability in a region in which chips are disposed.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A semiconductor package according to an embodiment includes an insulating layer; a first electrode part disposed on the insulating layer; a through electrode passing through the insulating layer and electrically connected to the first electrode part; and a reinforcement part disposed in the insulating layer; a connection part disposed on the first electrode part; and a chip mounted on the connection part, and wherein at least a portion of the reinforcement part vertically overlaps the chip and is not connected to the through electrode.

In addition, a thickness of the reinforcement part is greater than a thickness of the first electrode part.

In addition, the reinforcement part vertically overlaps a corner region of the chip.

In addition, the insulating layer includes a plurality of insulating layers including different insulating materials, and the reinforcement part is disposed in at least one of the plurality of insulating layers to overlap the chip in a vertical direction.

In addition, the plurality of insulating layers comprise a first insulating layer provided with a first insulating material, a second insulating layer disposed on the first insulating layer and including a second insulating material different from the first insulating material, and a third insulating layer disposed on the second insulating layer and including a third insulating material different from the first and second insulating materials, and wherein the reinforcement part is disposed in at least one of the first to third insulating layers.

In addition, the chip includes a first chip and a second chip spaced apart from the first chip in a horizontal direction, and the reinforcement part includes a first reinforcement part vertically overlaps the first chip, a second reinforcement part vertically overlaps the second chip, and a third reinforcement part vertically overlapping a region between the first and second chips.

In addition, the through electrode includes a first through electrode passing through at least one of the first and second insulating layers, the first through electrode includes first-first through electrode and first-second through electrode spaced apart from each other in a horizontal direction, and a width of the first-first through electrode is different from that of the first-second through electrode.

In addition, the first-first through electrode overlaps the chip in a vertical direction, the first-second through electrode does not overlap the chip in the vertical direction, and a width of the first-first through electrode is greater than that of the first-second through electrode.

In addition, the semiconductor package further comprises a second electrode part disposed on at least one of the first insulating layer and the second insulating layer, the second electrode part includes a second-first electrode part and a second-second electrode part spaced apart from each other in a horizontal direction, and a thickness of the second-first electrode part is different from that of the second-second electrode part.

In addition, the second-first electrode part overlaps the chip in a vertical direction, the second-second electrode part does not overlap the chip in the vertical direction, and the thickness of the second-first electrode part is greater than that of the second-second electrode part.

Meanwhile, a semiconductor package according to another embodiment comprises a first insulating layer; a second insulating layer disposed on the first insulating layer; a first electrode part disposed on the second insulating layer; a second electrode part disposed between the first and second insulating layers; a through electrode passing through the second insulating layer and electrically connected to the first and second electrode parts; a connection part disposed on the first electrode part; and a chip disposed on the connection part, and wherein a size of at least one of a second electrode part and a through electrode vertically overlapping the chip is different from a size of at least one of a second electrode part and a through electrode that does not vertically overlap the chip.

In addition, the second electrode part includes a second-first electrode part vertically overlapping the chip; and a second-second electrode part horizontally overlapping the second-first electrode part without vertically overlapping the chip, and wherein a thickness of the second-first electrode part above is greater than that of the second-second electrode part.

In addition, the thickness of the second-first electrode part satisfies a range of 120% to 160% of a thickness of the second-second electrode part.

In addition, the through electrode includes a first through electrode vertically overlapped with the chip; and a second through electrode horizontally overlapping the first through electrode without vertically overlapping the chip, and wherein a width of the first through electrode is greater than a width of the second through electrode.

In addition, the width of the first through electrode satisfies a range of 120% to 160% of the width of the second through electrode.

### Advantageous Effects

The semiconductor package according to an embodiment may include an insulating layer, a first electrode part, and a chip. The semiconductor package may include a reinforcement part disposed in a region overlapping the chip in a vertical direction among an entire region of the insulating layer. The reinforcement part may function to improve rigidity in a region overlapping the chip the vertical direction. Accordingly, the embodiment may prevent a region overlapping the chip from being greatly bent in a specific direction. The embodiment may improve physical and electrical reliability of a mounting pad or chip trace of the first electrode part disposed in a region overlapping the chip in a vertical direction, and thus improve operation characteristics of the chip. Accordingly, an electronic product, a server, and/or the like to which the semiconductor package according to an embodiment is applied may operate stably.

In addition, when a plurality of chips are mounted on the semiconductor package, the reinforcement part may vertically overlap a region between the plurality of chips. Accordingly, the embodiment may prevent bending in a specific direction in a region between the plurality of chips. Accordingly, the embodiment may solve the problem of deteriorating the physical reliability of chip traces connecting the plurality of chips.

In addition, the embodiment may include a through electrode disposed in the circuit board. In this case, the through electrode may include a first through electrode disposed in a region overlapping the chip in a vertical direction and a second through electrode that does not overlap the chip in a vertical direction. Widths of the first through electrode and the second through electrode may be different from each other. For example, the first through electrode overlapping the chip in a vertical direction may be greater than the width of the second through electrode. Accordingly, an embodiment may improve warpage characteristics in a region overlapping the chip in a vertical direction by increasing a width of the first through electrode disposed in a region vertically overlapping the chip with respect to a width of the second through electrode. An embodiment may have a structure in which a through electrode is disposed in a region vertically overlapping the chip. Accordingly, an embodiment may improve warpage characteristics in a region overlapping the chip in a vertical direction without affecting circuit integration.

In addition, the embodiment may include a second electrode part spaced apart from the first electrode part in a thickness direction. The second electrode part may include a second-first electrode part that does not overlap a chip in a vertical direction and a second-second electrode part that does not overlap the chip in a vertical direction. The thickness of the second-first electrode part and the thickness of the second-second electrode part may be different from each other.

For example, a thickness of the second-first electrode part disposed in a region vertically overlapping the chip may be greater than a thickness of the second-second electrode part. The embodiment may improve warpage characteristics in the region vertically overlapping the chip by increasing the thickness of the second-first electrode part disposed in the region vertically overlapping the chip with respect to the thickness of the second-second electrode part. Accordingly, the embodiment may improve warpage characteristics in the region vertically overlapping the chip without affecting circuit integration.

### DESCRIPTION OF DRAWINGS

FIG. 1 is a diagram showing a semiconductor package according to a comparative example.

FIG. 2 is a diagram schematically showing a semiconductor package according to a first embodiment.

FIG. 3 is a diagram showing a first detailed structure of the semiconductor package of FIG. 2.

FIG. 4 is a diagram showing a second detailed structure of the semiconductor package of FIG. 2.

FIG. 5 is a diagram showing a third detailed structure of the semiconductor package of FIG. 2.

FIG. 6 is a diagram showing a first arrangement structure of the reinforcement parts included in FIGS. 3 to 5.

FIG. 7 is a diagram showing a second arrangement structure of reinforcement parts provided in FIGS. 3 to 5.

FIG. 8A is a diagram showing a semiconductor package according to a second embodiment.

FIG. 8B is a plan view schematically showing the semiconductor package of FIG. 8A according to an embodiment.

FIG. 8C is a plan view schematically showing the semiconductor package of FIG. 8A according to another embodiment.

FIG. 9 is a diagram showing a first detailed structure of a semiconductor package according to a third embodiment.

FIG. 10 is a diagram showing a second detailed structure of a semiconductor package according to a third embodiment.

FIG. 11 is a diagram showing a first detailed structure of a semiconductor package according to a fourth embodiment.

FIG. 12 is a diagram showing a second detailed structure of a semiconductor package according to a fourth embodiment.

FIGS. 13 to 22 are diagrams showing a method of manufacturing the semiconductor package shown in FIG. 4 in order of processes.

### MODES OF THE INVENTION

Hereinafter, embodiments of the present invention will be described in detail with reference to the accompanying drawings.

However, the spirit and scope of the embodiment is not limited to a part of the embodiments described, and may be implemented in various other forms, and within the spirit and scope of the present invention, one or more of the elements of the embodiments may be selectively combined and replaced.

In addition, unless expressly otherwise defined and described, the terms used in the embodiments of the present invention (including technical and scientific terms may be construed the same meaning as commonly understood by one of ordinary skill in the art to which this invention belongs, and the terms such as those defined in commonly used dictionaries may be interpreted as having a meaning that is consistent with their meaning in the context of the relevant art.

In addition, the terms used in the embodiments of the present invention are for describing the embodiments and are not intended to limit the present invention. In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present invention, the terms such as first, second, A, B, (a), and (b) may be used. These terms are only used to distinguish the elements from other elements, and the terms are not limited to the essence, order, or order of the elements. In addition, when an element is described as being “connected”, or “coupled” to another element, it may include not only when the element is directly “connected” to, or “coupled” to other elements, but also when the element is “connected”, or “coupled” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements. Furthermore, when expressed as “on (over)” or “under (below)”, it may include not only the upper direction but also the lower direction based on one element.

### Comparative Example

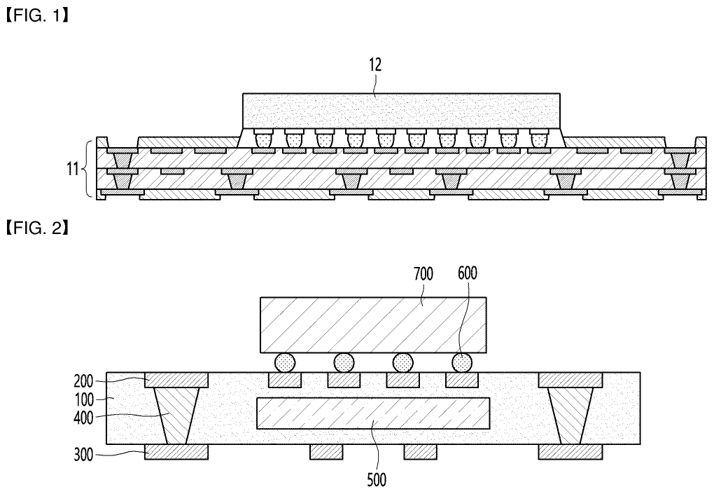

FIG. 1 is a diagram illustrating a semiconductor package according to a comparative example.

Referring to FIG. 1, a semiconductor package in a comparative example includes a circuit board 11.

The circuit board 11 includes a plurality of insulating layers. Electrode parts are disposed on the plurality of insulating layers.

The electrode part of the circuit board 11 may be disposed on upper and lower surfaces of the plurality of insulating layers, respectively. A first electrode part corresponding to a mounting pad on which a chip 12 is mounted is disposed on an outermost insulating layer among the plurality of insulating layers.

A chip 12 is mounted on the first electrode part. The chip 12 may be a processor chip. Although one chip is illustrated as being mounted on the first electrode part, two or more chips may be mounted on the first electrode part.

At this time, in the circuit board 11, an electrode part including a refined electrode pattern is required in order to mount a plurality of chips and to connect the plurality of chips.

In addition, the circuit board 11 is thinning each thickness of the plurality of insulating layers in order to slim down the semiconductor package.

In this case, when the thickness of the plurality of insulating layers becomes thinner, warpage characteristics of the circuit board 11 may deteriorate, and furthermore, the warpage characteristics of the semiconductor package may deteriorate.

When the warpage characteristics of the circuit board and the semiconductor package are deteriorated, there may be problems in physical and electrical reliability of the first electrode part connected to the chip 12.

That is, the first electrode part includes a fine trace for connecting the plurality of chips while the plurality of chips are mounted. The trace may be intensively disposed in a region vertically overlapping the chip 12 among an entire region of the circuit board 11.

In this case, when a warpage occurs in the circuit board 11, a stress caused by the warpage is transmitted to the trace. In this case, since the trace has a fine line width, it is vulnerable to stress caused by the warpage. For example, when the stress caused by the warpage is transmitted to the trace, physical reliability in which the trace is separated from the insulating layer may occur. When the stress caused by the warpage is transmitted to the trace, a physical and electrical reliability problem occurs in which the chip 12 mounted on the first electrode part is separated from the circuit board 11 by the stress.

In addition, recent electrical/electronic products are becoming more high-performance, and accordingly, technologies for mounting a larger number of chips on a substrate having a limited size are being researched. Therefore, a line width of a trace of the first electrode part is increasingly becoming finer. Accordingly, a method of improving warpage characteristics of the semiconductor package is being sought.

Furthermore, in recent years, functions processed by application processors (AP) increase, and accordingly, it is becoming difficult to implement an application processor on a single chip. Accordingly, mounting of a plurality of application processors on a single circuit board is required. In addition, the number of terminals included in each of the plurality of application processors is increasing due to 5G, Internet of Things (IoT), increased image quality, and increased communication speed. As a result, the number of traces of the first electrode part of the circuit board is increasingly increasing, and accordingly, the trace is becoming more refined.

An embodiment improves warpage characteristics of a semiconductor package in the semiconductor package in which at least one chip is disposed, thereby minimizing stress transmitted to a first electrode part connected to the chip. Furthermore, an embodiment solves an electrical reliability problem, a physical reliability problem, and a problem in which an operation characteristic (e.g., an operation speed) of the chip is deteriorated, which are generated as stress caused by a warpage of the semiconductor package is transmitted to the chip.

Furthermore, the embodiment allows a plurality of application processor chips to be disposed side by side on a single circuit board, while improving the operational reliability of the above multiple application processors.

### Electronic Device

Before describing the embodiment, an electronic device including the semiconductor package of the embodiment will be briefly described. An electronic device includes a main board (not shown). The main board may be physically and/or electrically connected to various components. For example, the main board may be connected to a semiconductor package of the embodiment. Various semiconductor devices may be mounted on the semiconductor package. The semiconductor package may include memory chips such as volatile memory (e.g., DRAM), non-volatile memory (e.g., ROM), and flash memory, application processor chips such as central processors (e.g., CPUs), graphics processors (e.g., GPUs), digital signal processors, encryption processors, microprocessors, and microcontrollers, and logic chips such as analog-to-digital converters and application-specific ICs (ASICs).

In addition, the embodiment provides a semiconductor package capable of mounting at least two chips of different types on one substrate while reducing a thickness of the semiconductor package connected to the main board of the electronic device.

In this case, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

### Embodiment

Hereinafter, a circuit board and a semiconductor package including the circuit board according to an embodiment will be described in detail. Here, a division of the circuit board and the semiconductor package may be made depending on whether the chip is mounted or not. For example, a substrate before the chip is mounted may be referred to as a circuit board, and a state in which the chip is mounted on the circuit board may be referred to as a semiconductor package.

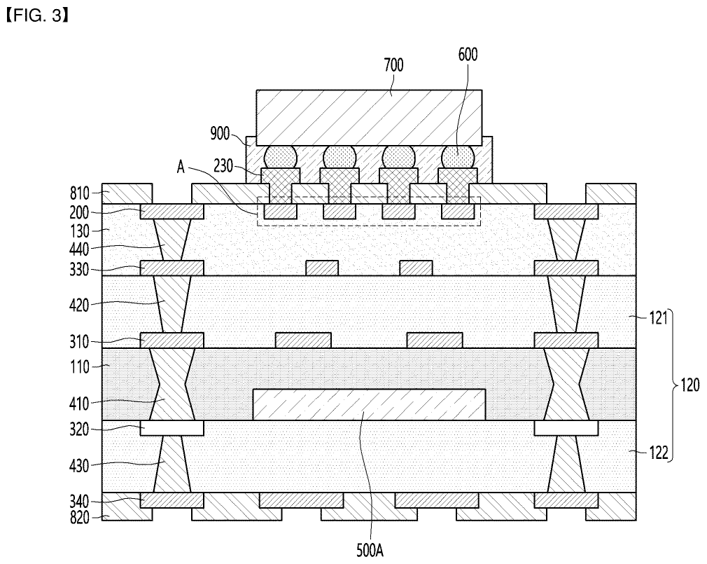

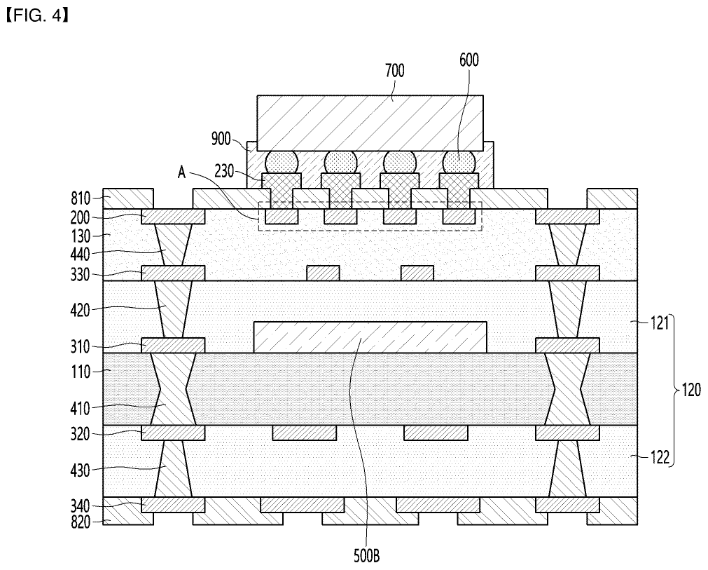

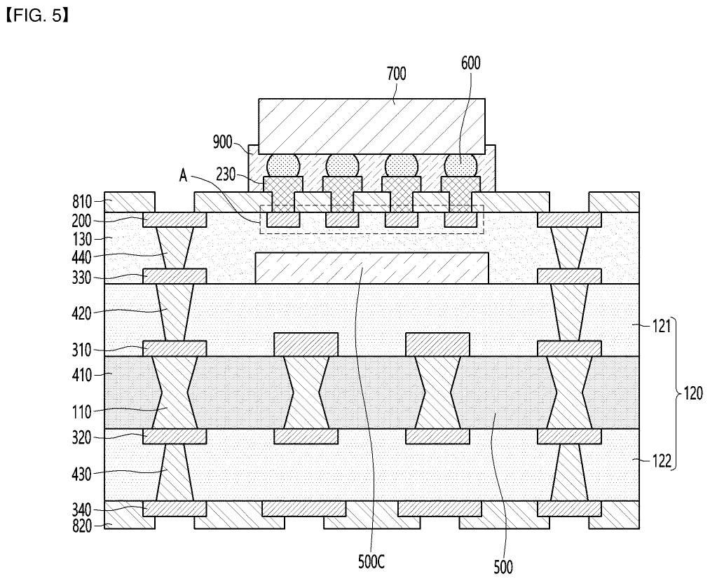

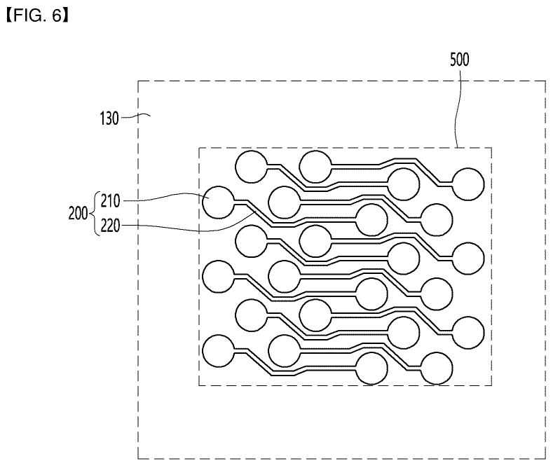

FIG. 2 is a diagram schematically showing a semiconductor package according to a first embodiment, FIG. 3 is a diagram showing a first detailed structure of the semiconductor package of FIG. 2, FIG. 4 is a diagram showing a second detailed structure of the semiconductor package of FIG. 2, FIG. 5 is a diagram showing a third detailed structure of the semiconductor package of FIG. 2, FIG. 6 is a diagram showing a first arrangement structure of the reinforcement parts included in FIGS. 3 to 5, and FIG. 7 is a diagram showing a second arrangement structure of reinforcement parts provided in FIGS. 3 to 5.

Hereinafter, a circuit board and a semiconductor package including the same according to a first embodiment will be described in detail with reference to FIGS. 2 to 7.

The circuit board and the semiconductor package according to the first embodiment may include a reinforcement part 500 to improve warpage characteristics. The reinforcement part 500 may reinforce a weak structure of the electrode part according to warpage characteristics of the semiconductor package. For example, the reinforcement part 500 may be embedded in the circuit board. In particular, the reinforcement part 500 may be disposed in a region that is vulnerable to a warpage in the circuit board. For example, the reinforcement part 500 may be provided to vertically overlap at least a portion of a region in which a chip is disposed in a semiconductor package. Preferably, the reinforcement part 500 may be provided to overlap a region and circumferential direction in which the chip is disposed along the vertical direction.

The reinforcement part 500 may have a predetermined thickness. For example, the reinforcement part 500 may be provided with a predetermined thickness in the insulating layer. The thickness of the reinforcement part 500 may be less than that of the insulating layer. An embodiment may prevent the reinforcement part 500 from protruding outward, thereby improving physical reliability and electrical reliability of the semiconductor package.

In addition, the thickness of the reinforcement part 500 may be greater than a thickness of an electrode part. For example, the reinforcement part 500 may be greater than thicknesses of electrode parts described below. Accordingly, the embodiment may allow the rigidity of the electrode part to be secured by the reinforcement part 500, and may prevent the semiconductor package from being greatly bent in a specific direction.

Hereinafter, a semiconductor package according to an embodiment and an arrangement structure of a reinforcement part included in the semiconductor package will be described in detail.

Referring to FIG. 2, a semiconductor package according to an embodiment may include a circuit board and a chip 700 mounted on the circuit board. The chip may include at least one of a processor chip and a memory chip. For example, the semiconductor package according to a first embodiment may have a structure in which one chip is mounted. The mounted chip 700 may include any one of memory chips such as volatile memory (e.g., DRAM), non-volatile memory (e.g., ROM), and flash memory, application processor chips such as central processors (e.g., CPUs), graphics processors (e.g., GPUs), digital signal processors, encryption processors, microprocessors, and microcontrollers, and logic chips such as analog-to-digital converters and application-specific ICs (ASICs).

The circuit board of the semiconductor package may include an insulating layer 100. The insulating layer 100 may be provided in a plurality of layers. However, the embodiment is not limited thereto. For example, the insulating layer 100 may be provided in one layer according to a type of the mounted chip 700 or specifications required by the semiconductor package.

An electrode part and a through electrode may be disposed on or in the insulating layer 100. In this case, the electrode part and the through electrode may be referred to as a wiring part. For example, the electrode part and the through electrode may be referred to as a wiring part electrically connected to the chip 700.

Specifically, a first electrode part 200 may be disposed on one surface of the insulating layer 100. The first electrode part 200 may refer to an electrode on which a chip is mounted. For example, the first electrode part 200 may include a plurality of mounting pads on which a chip is mounted and traces connected to the plurality of mounting pads.

In this case, when the insulating layer 100 is provided with a plurality of layers, the first electrode part 200 may be disposed on an upper surface of an insulating layer disposed on an uppermost side of the plurality of layers. Preferably, the first electrode part 200 may be embedded in an upper surface region of the insulating layer disposed on the uppermost side. Here, being embedded may mean that at least a portion of the upper surface of the first electrode part 200 is not covered by the insulating layer 100, but at least a portion of a side surface and a lower surface of the first electrode part 200 are covered by the insulating layer 100.

A second electrode part 300 may be disposed on the other surface of the insulating layer 100. When the insulating layer 100 is provided as one layer, the second electrode part 300 may refer to an outermost electrode part disposed on a lower surface of the insulating layer 100. When the semiconductor package according to an embodiment is connected to an electronic device, the second electrode part 300 may function as a terminal pad to be connected to the electronic device. In addition, when the insulating layer 100 is provided with a plurality of layers, the second electrode part 300 may refer to an electrode part disposed on a lower surface of at least one of the plurality of layers.

A through electrode 400 may be disposed in the insulating layer 100. The through electrode 400 may pass through the insulating layer 100.

The through electrode 400 may electrically connect the first electrode part 200 and the second electrode part 300. For example, one surface of the through electrode 400 may be connected to the first electrode part 200, and the other surface of the through electrode 400 may be connected to the second electrode part 300.

The reinforcement part 500 may be disposed in the insulating layer 100. The reinforcement part 500 may overlap the through electrode 400 in a horizontal direction. When the insulating layer 100 is provided as a single layer, the reinforcement part 500 may not overlap the through electrode 400 in a vertical direction. In addition, when the insulating layer 100 is provided with two or more layers, the reinforcement part 500 may vertically overlap a through electrode disposed in at least one insulating layer, and may not vertically overlap a through electrode disposed in at least one other insulating layer.

For example, when the insulating layer 100 is provided with a plurality of two or more layers, the reinforcement part 500 may be disposed in any one of the plurality of insulating layers. In addition, a through electrode passing through an insulating layer in which the reinforcement part 500 is disposed may not overlap the reinforcement part 500 in a vertical direction.

Accordingly, the reinforcement part 500 of the embodiment may not be connected to the through electrode 400. Preferably, the reinforcement part 500 may not be electrically connected to the through electrode 400. For, the reinforcement part 500 may be disposed within the insulating layer 100 to avoid a region where the through electrode 400 is disposed. For example, the insulating layer 100 may include a reinforcement region in which the reinforcement part 500 is disposed. The through electrode 400 may be disposed in the insulating layer 100 except for the reinforcement region.

Meanwhile, a bump 230 may be provided on the first electrode part 200. The bump 230 may be a post bump. The bump 230 may be disposed on first electrode patterns disposed in a region vertically overlapping the chip 700 among first electrode patterns of the first electrode part 200.

The bump 230 may facilitate coupling between the chip 700 and the circuit board. The bump 230 may be referred to as a protrusion protruding from the insulating layer of the circuit board.

That is, a pitch of terminals provided at the chip 700 is refined, and a short circuit may occur between a plurality of connection parts 600 connected to a plurality of terminals of the chip 700, respectively, by a connection part such as solder. Accordingly, in the embodiment, thermal compression bonding may be performed to reduce a volume of the connection part 600. Accordingly, the bump 230 may be provided on the first electrode part 200 of the embodiment, thereby improving an adjustment degree between the first electrode part 200 and the terminals of the chip 700.

In addition, when the connection part 600 is disposed, an intermetallic compound (IMC) may be diffused into the first electrode part 200. The intermetallic compound may have relatively low rigidity and low electrical conductivity. Accordingly, the bump 230 may be disposed on the first electrode part 200, thereby preventing diffusion of the intermetallic compound.

The connection part 600 may be disposed on the bump 230. The connection part 600 may have various shapes. For example, the connection part 600 may include a spherical shape. For example, the connection part 600 may have a circular shape or a semicircular shape. For example, a vertical cross section of the connection part 600 may have a partially or entirely rounded shape. For example, a vertical cross-sectional shape of the connection part 600 may be a flat surface at one side and a curved surface at the other side. In this case, the connection part 600 may be a solder ball, but is not limited thereto.

Meanwhile, the connection part 600 may have a hexahedral shape which does not include a curved surface. For example, a vertical cross-sectional shape of the connection part 600 may include a rectangular shape. For example, a vertical cross-sectional shape of the connection part 600 may include a rectangular or square shape.

The chip 700 may be mounted on the connection part 600. The chip 700 may be an application processor chip as described above, or may be a memory chip differently.

Meanwhile, the reinforcement part 500 may overlap the chip 700 in the vertical direction. Preferably, at least a portion of the reinforcement part 500 may overlap the chip 700 in the vertical direction.

That is, first electrodes of the first electrode part 200 disposed in a region vertically overlapping the chip 700 may be vulnerable to stress caused by warpage. For example, the first electrodes disposed in the region vertically overlapping the chip 700 may be easily cracked by stress or may be separated from the insulating layer 100.

Accordingly, warpage characteristics in one region of the insulating layer 100 on which the first electrodes are disposed may be important. Therefore, the embodiment may allow the reinforcement part 500 to be disposed corresponding to a region in which the first electrodes are disposed among the entire region of the insulating layer 100. Preferably, in an embodiment, the reinforcement part 500 may be disposed in a region vertically overlapping a region in which the first electrodes are disposed among entire region of the insulating layer 100. More preferably, in an embodiment, the reinforcement part 500 may be disposed in a region vertically overlapping the chip 700 among the entire region of the insulating layer 100.

In this case, the reinforcement part 500 may include various materials. For example, the reinforcement part 500 may include silicon, but is not limited thereto. For example, the reinforcement part 500 may include ceramic. However, in an embodiment, the reinforcement part 500 may not be in contact with the first electrode part 200, the second electrode part 300, and the through electrode 400. For example, the reinforcement part 500 may be electrically insulated from the first electrode part 200, the second electrode part 300, and the through electrode 400. Accordingly, the reinforcement part 500 may be formed of a metallic material.

Meanwhile, when the insulating layer 100 is provided with a plurality of layers, the reinforcement part 500 may be disposed to vertically overlap the chip 700 in any one of the plurality of layers. However, an embodiment is not limited thereto. For example, the reinforcement part 500 may be disposed to vertically overlap the chip 700 in each of at least two layers of the plurality of layers.

Hereinafter, a detailed layer structure of a semiconductor package according to an embodiment will be described in more detail.

Referring to FIG. 3, the insulating layer 100 of the semiconductor package may include a plurality of layers.

For example, the insulating layer 100 may have at least two or more layer structures.

In this case, the insulating layer 100 may include a plurality of insulating layers including different insulating materials.

Specifically, the insulating layer 100 may include a first insulating layer 110. The first insulating layer 110 may mean an insulating layer disposed inside rather than an outermost insulating layer among the plurality of layers of the insulating layer 100.

Preferably, the first insulating layer 110 may mean a core layer. For example, the first insulating layer 110 may be a clad copper laminated (CCL) including a prepreg (PPG) having a predetermined thickness, but is not limited thereto. For example, the first insulating layer 100 may include a material such as silicon, sapphire, glass, and ceramic. However, in an embodiment, the first insulating layer 110 is a core layer, and thus may include glass or sapphire, which is a transparent material. Accordingly, an embodiment may improve a warpage characteristic of a circuit board and a warpage characteristic of a semiconductor package due to modulus rigidity of the first insulating layer 110, which is the core layer. Also, the insulating layer 100 of an embodiment may be provided as layers including different insulating materials. In addition, widths or thicknesses of through electrodes or electrode parts disposed in insulating layers including different insulating materials may be different from each other. Accordingly, the embodiment allows the insulating layer 100 to include the first insulating layer 110 of the core layer, thereby improving the physical reliability of an entire layer structure of the semiconductor package.

In this case, when the first insulating layer 110, which is the core layer above, contains a transparent material such as sapphire or glass, alignment between insulating layers stacked above and below may be easily performed due to the transparent characteristics of the first insulating layer 110, thereby improving processability and product quality. For example, in an embodiment, when through electrodes are formed on the first insulating 110 and the second insulating layer disposed on the first insulating layer 110, the accuracy of the location of the through electrodes may be increased, and accordingly, it is possible to easily check whether the through electrode is defective or whether the electrode part is defective. In addition, the embodiment may improve the overall characteristics of the circuit board and even the overall characteristics of the semiconductor package by the material characteristics of the first insulating layer above (110), which is the core layer.

Meanwhile, the insulating layer 100 includes a second insulating layer 120 disposed on the first insulating layer 110. The second insulating layer 120 may include an insulating material included in the first insulating layer 110, but is not limited thereto.

For example, the second insulating layer 120 may include a prepreg. However, the second insulating layer 120 may have a thickness smaller than that of the first insulating layer 110. Accordingly, the first insulating layer 110 may be referred to as a core layer, and the second insulating layer 120 may be a build-up layer disposed on the first insulating layer 110.

The prepreg of the second insulating layer 120 may be formed by impregnating a fiber layer in the form of a fabric sheet, such as a glass fabric woven with glass yarn, with an epoxy resin, and then performing thermocompression. However, the embodiment is not limited to this, and the prepreg constituting the second insulating layer 120 may include a fiber layer in the form of a fabric sheet woven with carbon fiber yarn.

The second insulating layer 120 may include a resin and a reinforcing fiber disposed in the resin. The resin may be an epoxy resin, but is not limited thereto. The resin is not particularly limited to the epoxy resin, and for example, one or more epoxy groups may be included in the molecule, or alternatively, two or more epoxy groups may be included, or alternatively, four or more epoxy groups may be included. In addition, the resin of the second insulating layer 120 may include a naphthalene group, for example, may be an aromatic amine type, but is not limited thereto. For example, the resin may be include a bisphenol A type epoxy resin, a bisphenol F type epoxy resin, a bisphenol S type epoxy resin, a phenol novolac type epoxy resin, an alkylphenol novolac type epoxy resin, a biphenyl type epoxy resin, an aralkyl type epoxy resin, dicyclopentadiene type epoxy resin, naphthalene type epoxy resin, naphthol type epoxy resin, epoxy resin of condensate of phenol and aromatic aldehyde having phenolic hydroxyl group, biphenyl aralkyl type epoxy resin, fluorene type epoxy resin resins, xanthene-type epoxy resins, triglycidyl isocyanurate, rubber-modified epoxy resins, phosphorous-based epoxy resins, and the like, and naphthalene-based epoxy resins, bisphenol A-type epoxy resins, and phenol novolac epoxy resins, cresol novolak epoxy resins, rubber-modified epoxy resins, and phosphorous-based epoxy resins. In addition, the reinforcing fiber may include glass fiber, carbon fiber, aramid fiber (e.g., aramid-based organic material), nylon, silica-based inorganic material or titania-based inorganic material. The reinforcing fibers may be arranged in the resin to cross each other in a planar direction.

Meanwhile, the embodiment may use as the glass fiber, carbon fiber, aramid fiber (e.g., aramid-based organic material), nylon, silica-based inorganic material or titania-based inorganic material.

The second insulating layer 120 may have a thickness in a range of 10 μm to 30 μm. For example, the second insulating layer 120 may satisfy a thickness in a range of 15 μm to 25 μm. For example, the second insulating layer 120 may satisfy a thickness in a range of 18 μm to 23 μm. When the thickness of the second insulating layer 120 is less than 10 μm, the electrode part may not be stably disposed on the upper surface or the lower surface of the second insulating layer 120. In addition, when the thickness of the second insulating layer 120 is less than 10 μm, warpage characteristics of the circuit board according to an embodiment may be deteriorated, and thus physical or electrical reliability may be deteriorated. In addition, when the thickness of the second insulating layer 120 exceeds 30 μm, the overall thickness of the circuit board may be increased. In addition, when the thickness of the second insulating layer 120 exceeds 30 μm, a line width of an electrode part disposed on the upper surface or the lower surface of the second insulating layer 120 or a spacing between the electrodes may increase.

Meanwhile, the second insulating layer 120 may be provided with a plurality of layers. For example, the second insulating layer 120 may be provided with a plurality of layers on at least one side of the first insulating layer 110.

For example, the second insulating layer 120 may include a second-first insulating layer 121 disposed on an upper surface of the first insulating layer 110 and a second-second insulating layer 122 disposed on a lower surface of the first insulating layer 110.

At this time, the drawing shows that one layer of second-first insulating layer 121 is disposed on the upper surface of the first insulating layer 110, and on layer of second-second insulating layer 122 is disposed on the lower surface of the first insulating layer 110, but is not limited thereto. For example, two or more second-first insulation layers may be disposed on the upper surface of the first insulation layer 110. For example, two or more second-second insulation layers may be disposed on the lower surface of the first insulation layer 110.

Meanwhile, an embodiment may include a third insulating layer 130 including an insulating material different from that of the first insulating layer 110 and the second insulating layer 120. For example, the third insulating layer 130 may include an insulating material capable of refining a line width or a spacing of an electrode part. For example, the third insulating layer 130 may include a photosensitive resin. Preferably, the third insulating layer 130 may include Photo imageable dielectrics (PID).

To this end, the third insulating layer 130 may include an epoxy resin, a photo initiator, a silicon-based filler, a curing agent, and the like. For example, the third insulating layer 130 may be formed by laminating a photocurable resin film, or applying a photocurable resin paste or liquid phase. In this case, in one example, a material of the photocurable resin may include at least one selected from photocurable polyhydroxystyrene (PHS), photocurable polybenzooxazole (PBO), photocurable polyimide (PI), photocurable benzo cyclobutene (BCB), a photocurable poly siloxane, a photocurable epoxy, and a novolac resin.

In an embodiment, the third insulating layer 130 includes a photocurable resin such as PID, and accordingly, relatively fine circuit patterns and through electrodes may be formed. Preferably, the third insulating layer 130 may be an insulating layer disposed closest to the chip 700. At this time, the electrode part disposed in a region adjacent to the chip 700 may require miniaturization. Preferably, the number of terminals of the chip 700 are increasing, and accordingly, miniaturization of the first electrode part 200 may be required to be connected to all terminals of the chip 700 within a limited space. Accordingly, in an embodiment, the third insulating layer 130 on which the first electrode part 200 is disposed may be formed of an insulating material including the photocurable resin as described above. Accordingly, in an embodiment, it is possible to miniaturize the first electrode part 200 disposed on the third insulating layer 130.

In this case, although the third insulating layer 130 is illustrated as being provided as a single layer in the drawing, the present invention is not limited thereto. Preferably, the third insulating layer 130 may be disposed on the second insulating layer 120 to have a plurality of layer structures. For example, in order to arrange a chip trace connecting the two or more chips when two or more chips are mounted on the semiconductor package, the third insulating layer 130 may have a layer structure of two or more layers. However, hereinafter, it will be described that the third insulating layer 130 is provided as a single layer.

The third insulating layer 130 may have a thickness smaller than each thickness of the first insulating layer 110 and the second insulating layer 120.

For example, the third insulating layer 130 may have a thickness ranging from 3 μm to 20 μm. For example, the third insulating layer 130 may have a thickness ranging from 4 μm to 18 μm. For example, the third insulating layer 130 may have a thickness ranging from 6 μm to 15 μm.

In this case, if the thickness of the third insulating layer 130 is less than 3 μm, the electrode part formed on the third insulating layer 130 may not be stably protected. In addition, if the thickness of the third insulating layer 130 exceeds 20 μm, it is difficult to miniaturize the electrode part or the through electrode disposed on the third insulating layer 130, and accordingly, it may not be possible to arrange all pads or traces connected to the chip 700 within a limited space.

Meanwhile, electrode parts are disposed on the first insulating layer 110, the second insulating layer 120, and the third insulating layer 130, respectively.

Preferably, the first insulating layer 110 may be disposed on an upper surface of the third insulating layer 130 disposed at an uppermost side of the plurality of insulating layers.

A second electrode part 300 may be disposed in a remaining region excluding an upper surface of the third insulating layer 130.

For example, a second-first electrode part 310 may be disposed on the upper surface of the first insulating layer 110. For example, a second-second electrode part 320 may be disposed on the lower surface of the first insulating layer 110. For example, a second-third electrode part 330 may be disposed on the upper surface of the second-first insulating layer 121. For example, a second-fourth electrode part 340 may be disposed on the lower surface of the second-second insulating layer 122.

In this case, the second-first electrode part 310, the second-second electrode part 320, the second-third electrode part 320, and the second-fourth electrode part 340 may have a thickness greater than that of the first electrode part 200, and may have a line width and a spacing greater than a spacing of electrodes of the first electrode part 200. This is because the third insulating layer 130 on which the first electrode part 200 is disposed includes a PID, which is a photosensitive resin, and the first insulating layer 110 and the second insulating layer 120 on which the second-first electrode part 310, the second-second electrode part 320, the second-third electrode part 320, and the second-fourth electrode part 340 are disposed include a prepreg.

For example, the first electrode part 200 may have a thickness ranging from 3 μm to 13 μm. For example, the first electrode part 200 may have a thickness ranging from 4 μm to 12 μm. For example, the first electrode part 200 may have a thickness ranging from 5 μm to 11 μm.

If the thickness of the first electrode part 200 is less than 5 μm, the resistance of the first electrodes of the first electrode part 200 increases, and thus electrical reliability may decrease in connection with the chip 700. In addition, If the thickness of the first electrode part 200 exceeds 11 μm, the line width or spacing of the first electrodes increase, and thus, all wires connected to the chip 700 may not be disposed within the limited space.

Each of the first electrodes of the first electrode part 200 may have a line width of 6 μm or less. For example, the first electrodes of the first electrode part 200 may have a line width of 5 μm or less. For example, the first electrodes of the first electrode part 200 may have a line width of 4 μm or less.

In addition, the first electrodes of the first electrode part 200 may be disposed with a spacing of 6 μm or less. In this case, the spacing may mean a distance between adjacent first electrodes among a plurality of first electrodes of the first electrode part 200. For example, the spacing may mean a spacing between a mounting pad and a trace among the first electrodes, a spacing between a mounting pad and a mounting pad, and a spacing between traces.

The first electrodes of the first electrode part 200 may have a spacing of 5 μm or less. For example, the first electrodes of the first electrode part 200 may have a spacing of 4 μm or less.

Preferably, the first electrode part 200 may have a line width of 1 μm to 6 μm. The line width may mean a line width of a trace among the first electrodes of the first electrode part 200. For example, a pad directly connected to the chip 700 among the first electrodes may have a width greater than a width the trace for the arrangement of the connection part.

The first electrode part 200 may have a line width in a range of 1.2 μm to 5 μm. The first electrode part 200 may have a line width in a range of 1.5 μm to 4 μm. If the line width of the first electrode part 200 is less than 1 μm, the resistance of the first electrodes of the first electrode part 200 increases, and thus, the loss in communication with the chip 700 may increase. For example, If the line width of the first electrode part 200 is less than 1 μm, a physical reliability problem in which the first electrode part 200 easily collapses due to an external factor may occur, and thus, the processability may be deteriorated in forming the first electrode part 200.

Meanwhile, if the line width of the first electrode part 200 is greater than 6 μm, it may be difficult to connect a plurality of processor chips in a limited space. For example, if the line width of the first electrode part 200 is greater than 6 μm, it may be difficult to arrange all traces for connecting a plurality of processor chips in a limited space. For example, if the line width of the second electrode part 200 is greater than 6 μm, an arrangement space for arranging traces for connecting a plurality of processor chips may increase, and accordingly, the overall size of the circuit board and a package substrate may increase.

Meanwhile, the second electrode part 300 may have a greater line width, a greater thickness, and a greater spacing than the first electrode part 200.

The first electrode part 200 and the second electrode part 300 may be formed of at least one metal material selected from gold (Au), silver (Ag), platinum (Pt), titanium (Ti), tin (Sn), copper (Cu), and zinc (Zn). In addition, the first electrode part 200 and the second electrode part 300 may be formed of a paste or solder paste including at least one metal material selected from gold (Au), silver (Ag), platinum (Pt), titanium (Ti), tin (Sn), copper (Cu), and zinc (Zn) having excellent bonding strength. Preferably, the first electrode part 200 and the second electrode part 300 may be formed of copper (Cu), which has high electrical conductivity and is relatively inexpensive. However, a layer structure of the first electrode part 200 and a layer structure of the second electrode part 300 may be different from each other. For example, the first electrode part 200 may be formed by performing electroplating on a seed layer formed by a sputtering method, in order to have a fine line width and spacing. Accordingly, the first electrode part 200 may include a first metal layer (not shown), a second metal layer (not shown), and a third metal layer (not shown). The first metal layer may be formed by a sputtering method, and may include titanium. The second metal layer may be formed on the first metal layer by a sputtering method, and may include copper. The third metal layer may be formed by electroplating using the first metal layer and the second metal layer as a seed layer, and may include copper.

Meanwhile, the first electrode part 200 and the second electrode part 300 may be formed by an additive process, a subtractive process, a modified semi additive process (MSAP) and a semi additive process (SAP) method, which is a typical circuit board manufacturing process, and a detailed description thereof will be omitted herein.

Meanwhile, a through electrode may be disposed in the insulating layer 100.

Preferably, through electrodes 400 may be disposed in the first insulating layer 110, the second insulating layer 120, and the third insulating layer 130, respectively.

For example, the through electrode 400 may include a first through electrode 410 disposed in the first insulating layer 110. In this case, the first through electrode 410 is disposed in the first insulating layer 110, which is a core layer having a relatively thick thickness. Accordingly, the first through electrode 410 may have an hourglass shape, but is not limited thereto. For example, a shape of the first through electrode 410 may vary according to a processing method of a through hole penetrating the first insulating layer 110.

Meanwhile, the first through electrode 410 may electrically connect the second-first electrode part 310 disposed on the upper surface of the first insulating layer 110 and the second-second electrode part 320 disposed on the lower surface of the first insulating layer 110.

Meanwhile, a second through electrode may be disposed in the second insulating layer 120. For example, a second-first through electrode 420 may be disposed in the second-first insulating layer 121. For example, a second-second through electrode 430 may be disposed in the second-second insulating layer 122.

The second-first through electrode 420 may electrically connect the second-first electrode part 310 disposed on the upper surface of the first insulating layer 110 and the second-third electrode part 330 disposed on the upper surface of the second-first insulating layer 121.

In addition, the second-second through electrode 430 may electrically connect the second-second electrode part 320 disposed on the lower surface of the first insulating layer 110 and the second-fourth electrode part 340 disposed on the lower surface of the second-second insulating layer 122.

A third through electrode 440 may be disposed on the third insulating layer 130. The third through electrode 440 may electrically connect the second-third electrode part 330 disposed on the upper surface of the second-first insulating layer 121 and the first electrode part 200 disposed on the upper surface of the third insulating layer 130. However, when the third insulating layer 130 is provided with a plurality of insulating layers, the third through electrode 440 may be disposed in different layers, and thus the first electrode part 200 and the second-third electrode part 330 may be connected through a plurality of third through electrodes.

Meanwhile, the through electrode as described above may be formed by filling the inside of the through hole penetrating each insulating layer with a conductive material. The through hole may be formed by any one of machining methods, including mechanical, laser, and chemical processing. When the through hole is formed by mechanical processing, methods such as milling, drilling, and routing may be used, and when the through hole is formed by laser processing, a UV or CO2 laser method may be used, and when the through hole is formed by chemical processing, drugs containing amino silane, ketones, etc. may be used, and the like, thereby at least one insulating layer among the plurality of insulating layers may be opened.

On the other hand, the processing by the laser is a cutting method that takes the desired shape to melt and evaporate a part of the material by concentrating optical energy on the surface, it can easily process complex formations by computer programs, and can process composite materials that are difficult to cut by other methods.

In addition, the processing by the laser can have a cutting diameter of at least 0.005 mm, and has a wide advantage in a range of possible thicknesses.

As the drill for the laser processing, it is preferable to use a YAG (Yttrium Aluminum Garnet) laser, a CO₂ laser, or an ultraviolet (UV) laser. The YAG laser is a laser that can process both the copper foil layer and the insulating layer, and the CO₂ laser is a laser that can process only the insulating layer.

When the through hole is formed, the through electrode may be formed by filling the inside of the through hole with a conductive material. A metal material forming the through electrode may be any one material selected from Cu, Ag, Sn, Au, Ni, and Pd, and the metal material may be filled using any one or a combination of electroless plating, electrolytic plating, screen printing, sputtering, evaporation, ink jetting and dispensing.

Meanwhile, the reinforcement part 500 is disposed in any one of the first insulating layer 110, the second insulating layer 120, and the third insulating layer 130. In this case, as in the first detailed structure of FIG. 3, the reinforcement part 500A may be disposed in the first insulating layer 110.

That is, the reinforcement part of an embodiment may be disposed in any one of the first insulating layer 110, the second insulating layer 120, and the third insulating layer 130. The reinforcement part 500A of the first detailed structure may be disposed in the first insulating layer 110.

The reinforcement part 500A may be disposed in the first insulating layer 110 and may not overlap the first through electrode 410 disposed in the first insulating layer 110 in a vertical direction.

The reinforcement part 500A may not be electrically connected to the first through electrode 410. In addition, the reinforcement part 500A may not be electrically connected to through electrodes disposed in an insulating layer other than the first through electrode 410.

In addition, the reinforcement part 500A may not be electrically connected to the first electrode part 200 and the second electrode part 300.

The reinforcement part 500A may include a region overlapping the chip 700 in a vertical direction. For example, at least a portion of the reinforcement part 500A may overlap the chip 700 in a vertical direction, thereby increasing the rigidity of the region overlapping the chip 700 in a vertical direction.

The embodiment may improve warpage characteristics in a region overlapping the chip 700 in a vertical direction. In addition, the embodiment may improve physical and electrical reliability of a mounting pad or chip trace of the first electrode part 200 disposed in a region overlapping the chip 700 in a vertical direction, and accordingly, operational characteristics of the chip 700 may be improved.

Meanwhile, the semiconductor package according to an embodiment includes a protective layer.

For example, the first protective layer 810 may be disposed on an upper surface of the first insulating layer 110. The first protective layer 810 may include an opening vertically overlapping the region in which the chip 700 is disposed. The bump 230 may penetrate the first protective layer 810. The bump 230 may protrude from the first protective layer 810.

In addition, the second protective layer 820 may be disposed on the lower surface of the second-second insulating layer 122.

The first protective layer 810 and the second protective layer 820 may be resist layers. For example, the first protective layer 810 and the second protective layer 820 may be solder resist layers including an organic polymer material. For example, the first protective layer 810 and the second protective layer 820 may include an epoxy acrylate-based resin. Specifically, the first protective layer 810 and the second protective layer 820 may include a resin, a curing agent, a photo initiator, a pigment, a solvent, a filler, an additive, an acrylic-based monomer, etc. However, the embodiment is not limited thereto, and the first protective layer 810 and the second protective layer 820 may be any one of a photo solder resist layer, a cover-lay, and a polymer material.

The first protective layer 810 and the second protective layer 820 may have a thickness of about 1 μm to about 20 μm. The first protective layer 810 and the second protective layer 820 may have a thickness of about 1 μm to about 15 μm. For example, the first protective layer 810 and the second protective layer 820 may have a thickness of about 5 μm to about 20 μm. If the thicknesses of the first protective layer 810 and the second protective layer 820 are greater than about 20 μm, the thickness of the circuit board may increase. If the thicknesses of the first protective layer 810 and the second protective layer 820 are less than about 1 μm, the electrical reliability or the physical reliability may deteriorate because circuit pattern layers included in the circuit board are not stably protected.

Meanwhile, a fillet layer 900 may be formed on the first insulating layer 110. The fillet layer 900 may be disposed to cover a part of an upper surface of the first insulating layer 100, a part of an upper surface of the first electrode part 1200, the connection part 600 and at least a part of the chip 700. The fillet layer 900 may prevent foreign substances or moisture from penetrating into a lower region of the chip 700.

In this case, although not shown in the drawings, a surface treatment layer (not shown) may be disposed on the electrode part vertically overlapping the openings of the first protective layer 810 and the second protective layer 820.

The surface treatment layer may be an organic solderability preservation (OSP) layer. For example, the surface treatment layer may be an organic layer formed of an organic material such as benzimidazole.

However, the embodiment is not limited thereto. For example, the surface treatment layer may be a plating layer. For example, the surface treatment layer may include at least one of a nickel (Ni) plating layer, a palladium (Pd) plating layer, and a gold (Au) plating layer.

Meanwhile, as illustrated in FIG. 4, the reinforcement part in a second detailed structure may be disposed in the second insulation layer 120. For example, a semiconductor package in the second detailed structure may include a reinforcement part 500B disposed in the second insulation layer 120. For example, the reinforcement part 500B may be disposed in the second-first insulation layer 121 disposed on the upper surface of the first insulation layer 110. That is, the reinforcement part 500 may be disposed as close as possible to the chip 700 or as close as the first electrode part 200. Accordingly, in an embodiment, the reinforcement part 500B is disposed in the second-first insulation layer 121 rather than the second-second insulation layer 122. Accordingly, in an embodiment, the warpage improvement effect by the reinforcement part 500B may be further improved as the reinforcement part 500B is disposed in a region adjacent to the first electrode part 200. For example, if the reinforcement part 500B is disposed in a region away from the first electrode part 200 in the thickness direction, a thickness or flat area of the reinforcement part must be increased to improve the warpage improvement effect. In this case, if the thickness or flat area of the reinforcement part increases, the thickness of the circuit board and the thickness of the semiconductor package may increase due to a decrease in circuit integration in the region in which the reinforcement part is disposed, and thus it may be difficult to slim down the semiconductor package. Accordingly, the embodiment may maximize the warpage improvement effect by using the reinforcement part 500B having a relatively small planar area and a relatively small thickness by allowing the reinforcement part 500B to be disposed in the second-first insulating layer 121 adjacent to the first electrode part 200.

Meanwhile, as illustrated in FIG. 5, the reinforcement part in the third detailed structure may be disposed in the third insulating layer 130. In this case, the third insulating layer 130 may substantially have a plurality of layer structures. A reinforcement part 500C may be disposed in any one of the third insulating layers 130 of the plurality of layers. In this case, when the third insulating layer 130 is provided with a plurality of layers, the reinforcement part 500C is disposed in an insulating layer adjacent to the first electrode part 200 as much as possible among the plurality of third insulating layers.

Meanwhile, in FIGS. 3 to 5, the reinforcement part 500 is illustrated as being disposed in only one of the first insulating layer 110, the second insulating layer 120, and the third insulating layer 130, but the present invention is not limited thereto. For example, the reinforcement part 500 may be disposed in at least two insulating layers. For example, the reinforcement part 500 may be disposed in each of the first insulating layer 110 and the second insulating layer 100. For example, the reinforcement part 500 may be disposed in each of the first insulating layer 110 and the third insulating layer 130. For example, the reinforcement part 500 may be disposed in each of the second insulating layer 120 and the third insulating layer 130.

Meanwhile, referring to a top view of the first electrode part 200 in FIG. 6, the first electrode part 200 includes a plurality of first electrodes. The plurality of first electrodes include a plurality of pads 210 connected to the chip 700 and a chip trace 220 connected to the plurality of pads 210. The plurality of pads 210 and the chip trace 220 are disposed in a region vertically overlapping the chip 700 among the upper surfaces of the third insulating layer 130.

In this case, the reinforcement part 500 may include all of 500A, 500B, and 500C included in FIGS. 3 to 5. In addition, the reinforcement part 500 may be disposed in a region vertically overlapping the chip 700. For example, the reinforcement part 500 may have a plate shape. For example, the reinforcement part 500 may include a reinforcing member having a single plate shape. The reinforcement part 500 may overlap the plurality of pads 210, the chip trace 220, and the bump 230 connected to the chip 700 in the vertical direction as a whole.

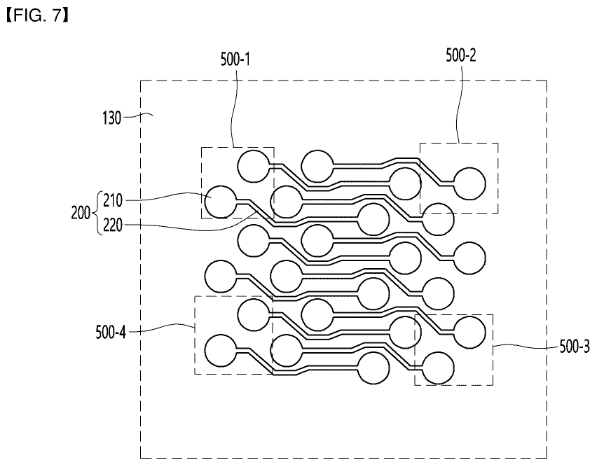

Meanwhile, referring to FIG. 7, the reinforcement part 500 of the embodiment may include a plurality of regions spaced apart from each other.

For example, the reinforcement part 500 may be disposed only in some of the regions vertically overlapping the chip 700. For example, the reinforcement part 500 may be disposed in a region vertically overlapping a corner region of the chip 700.

Preferably, the reinforcement part 500 may include a first reinforcement part 500-1 which vertically overlaps a first corner region of the chip 700. In addition, the reinforcement part 500 may include a second reinforcement part 500-2 spaced apart from the first reinforcement part 500-1 while overlapping the second corner region of the chip 700 in a vertical direction. In addition, the reinforcement part 500 may include a third reinforcement part 500-3 spaced apart from the first reinforcement part 500-1 and the second reinforcement part 500-2 while overlapping a third corner region of the chip 700 in a vertical direction. In addition, the reinforcement part 500 may include a fourth reinforcement part 500-4 spaced apart from the first to third reinforcement parts 500-1, 500-2, and 500-3 while overlapping a fourth corner region of the chip 700 in a vertical direction.

In this case, when the warpage characteristic is deteriorated, a greatest stress may occur in a region overlapping the corner region of the chip 700 in a vertical direction. Accordingly, an embodiment selectively arranges the reinforcement part 500 only in the region vertically overlapping the corner region of the chip 700. Accordingly, an embodiment may reduce an area occupied by the reinforcement part 500, and thus an electrode part or a through electrode may be disposed in a region between the first to fourth reinforcement parts. Accordingly, an embodiment may improve the warpage characteristic of the semiconductor package without significantly affecting circuit integration.

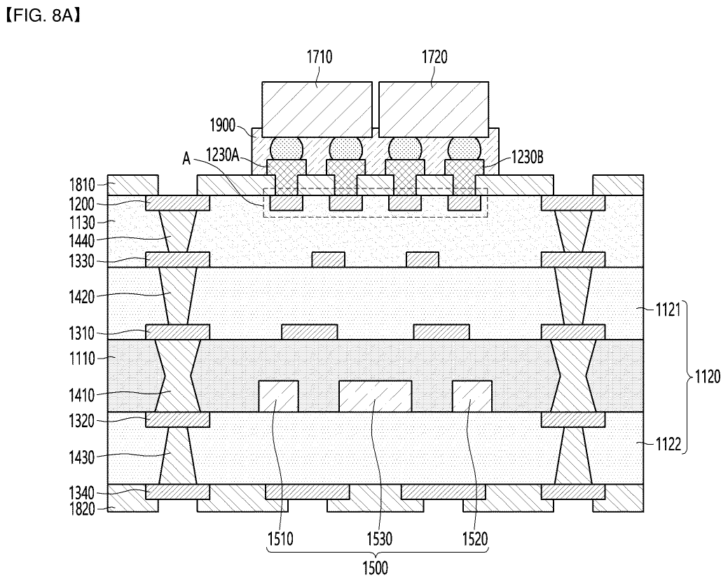

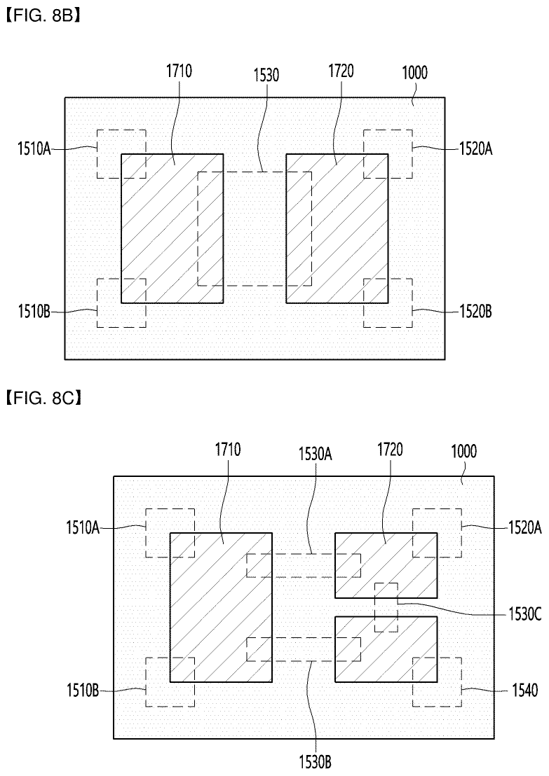

FIG. 8A is a diagram showing a semiconductor package according to a second embodiment, FIG. 8B is a plan view schematically showing the semiconductor package of FIG. 8A according to an embodiment, and FIG. 8C is a plan view schematically showing the semiconductor package of FIG. 8A according to another embodiment.

Referring to FIGS. 8A and 8B, a semiconductor package includes a first chip 1710 and a second chip 1720. That is, the semiconductor package according to the second embodiment may have a structure in which at least two chips are mounted. In this case, a chip of one (e.g., the first chip 1710) of the two chips may be any one of a plurality of processor chips. Also, the other chip (e.g., the second chip 1720) of the two chips may be the other one of a plurality of processor chips or a memory chip.

The semiconductor package may include a first insulating layer 1110, a second insulating layer 1120, 1211 and 1212, a third insulating layer 1130, a first electrode part 1200, a second electrode part 1310, 1320, 1330, 1340, a through electrode 1410, 1420, 1430, 1440, and a bump 1230.

Meanwhile, the first electrode part 1200 may be divided into a plurality of groups. For example, the first electrode part 1200 may be divided into a first group in which the first chip 1710 is disposed and a second group in which the second chip 1720 is disposed.

Also, the bump 1230 may include a first bump 1230A disposed on the first electrode part of the first group. Also, the bump 1230 may include a second bump 1230B disposed on the first electrode part of the second group.

In addition, a first connection part 1610 may be disposed on the first bump 1230A, and a second connection part 1620 may be disposed on the second bump 1230B.

Meanwhile, the reinforcement part 1500 may be disposed in at least one of the first insulating layer 1110, the second insulating layer 1120, and the third insulating layer 1130. Although the reinforcement part 1500 is illustrated as being disposed in the first insulating layer 1110, the embodiment is not limited thereto. For example, the reinforcement part 1500 may be disposed in the second insulating layer 1120 or the third insulating layer 1130 other than the first insulating layer 1110.

A plurality of reinforcement parts 1500 may be provided.

For example, the reinforcement part 1500 may include a first reinforcement part 1510 that vertically overlaps the first chip 1710. The first reinforcement part 1510 may vertically overlap the entire region of the first chip 1710, and differently, may vertically overlap a corner region. For example, the first reinforcement part 1510 may include a first-first reinforcement part 1510A that vertically overlaps a first corner region of the first chip 1710 and a first-second reinforcement part 1510B that vertically overlaps a second corner region of the first chip 1710.

The reinforcement part 1500 may include a second reinforcement part 1520 that vertically overlaps the second chip 1720. The second reinforcement part 1520 may vertically overlap an entire region of the second chip 1720, and differently, may vertically overlap a corner region of the second chip 1720. For example, the first reinforcement part 1510 may include a second-first reinforcement part 1520A that vertically overlaps a first corner region of the second chip 1720, and a second-second reinforcement part 1520B that vertically overlaps a second corner region of the second chip 1720.

The reinforcement part 1500 may further include a third reinforcement part 1530 spaced apart from the first reinforcement part 1510 and the second reinforcement part 1520. The third reinforcement part 1530 may overlap a region between the first chip 1710 and the second chip 1720 in a vertical direction. For example, the third reinforcement part 1530 may include a first portion that vertically overlaps the first chip 1710, a second portion that vertically overlaps the second chip 1720, and a third portion that vertically overlaps a region between the first chip 1710 and the second chip 1720.

As described above, when the semiconductor package has a structure in which a plurality of chips are mounted, the second embodiment allows the reinforcement part to vertically overlap the region between the plurality of chips, and it is possible to solve a problem in which the physical reliability of a chip trace connecting the plurality of chips is deteriorated due to a warpage occurring in a region between the plurality of chips.

Also, referring to FIG. 8C, a semiconductor package may include at least three chips. For example, the semiconductor package may include first to third chips 1710, 1720, and 1730.

The reinforcement part 1500 may include a first reinforcement part 1510 overlapping the first chip 1710 in a vertical direction. The first reinforcement part 1510 may overlap the entire region of the first chip 1710 in a vertical direction, and differently, may overlap a corner region of the first chip 1710 in a vertical direction. For example, the first reinforcement part 1510 may include a first-first reinforcement part 1510A that vertically overlaps ae first corner region of the first chip 1710 and a first-second reinforcement part 1510B that vertically overlaps a second corner region of the first chip 1710.

The reinforcement part 1500 may include a second reinforcement part 1520 that vertically overlaps the second chip 1720. The second reinforcement part 1520 may vertically overlap an entire region of the second chip 1720, and differently, may vertically overlap a corner region of the second chip 1720. For example, the second reinforcement part 1510 may include a second reinforcement part 1520A that vertically overlaps a first corner region of the second chip 1720.

The reinforcement part 1500 may include a fourth reinforcement part 1540 that vertically overlaps the third chip 1730. The fourth reinforcement part 1540 may vertically overlap a corner region of the third chip 1720.

The reinforcement part 1500 may further include a third reinforcement part 1530. The third reinforcement part 1530 may include a third-first reinforcement part 1530A that vertically overlaps a region between the first chip 1710 and the second chip 1720. Also, the third reinforcement part 1530 may include a third-second reinforcement part 1530B that vertically overlaps a region between the first chip 1710 and the third chip 1730. Also, the third reinforcement part 1530 may include a third-second reinforcement part 1530B that vertically overlaps a region between the first chip 1710 and the third chip 1730. Also, the third reinforcement part 1530 may include a third-third reinforcement part 1530C that vertically overlaps a region between the second chip 1720 and the third chip 1730.

Hereinafter, a third embodiment will be described.

Unlike the first and second embodiments, the third embodiment makes it possible to improve the warpage characteristics of the semiconductor package without including a reinforcement part.

For example, when the reinforcement part as shown in FIGS. 2 to 8C is disposed in the semiconductor package, even if an area of the reinforcement part is minimized, there is a problem that circuit integration is deteriorated corresponding to an planar area occupied by the reinforcement part. Accordingly, the embodiment may improve the warpage characteristics of the semiconductor package without affecting circuit integration.

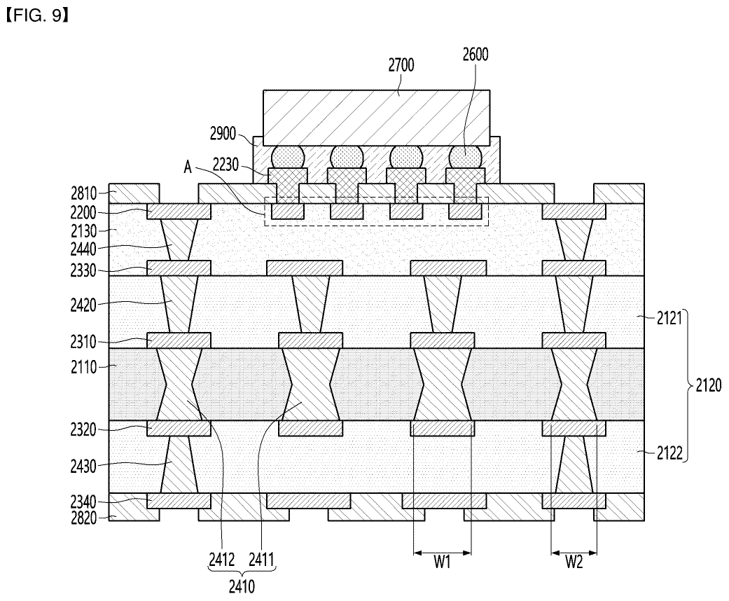

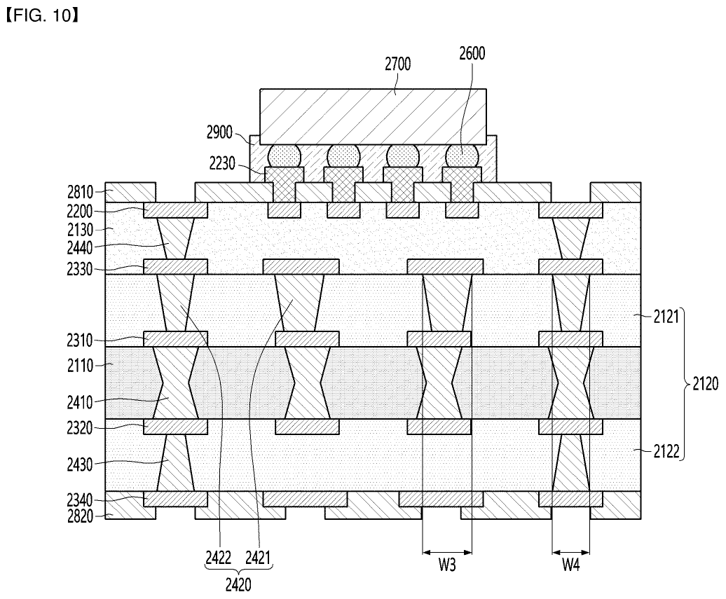

FIG. 9 is a diagram showing a first detailed structure of a semiconductor package according to a third embodiment, and FIG. 10 is a diagram showing a second detailed structure of a semiconductor package according to a third embodiment.

Referring to FIGS. 9 and 10, the third embodiment increases a size of a through electrode disposed in any one of a plurality of insulating layers. And, when the size of the through electrode increases, a warpage characteristic in a region in which the through electrode having an increased size is disposed may increase compared to a prior art. Accordingly, an embodiment improves warpage characteristics of a semiconductor package through a size change of the through electrode.

Referring to FIG. 9, the semiconductor package may include a first insulating layer 2110, a second insulating layer 2120, 2211, 2212, a third insulating layer 2130, a first electrode part 2200, a second electrode part 2310, 2320, 2330, 2340, and through electrodes 2410, 2420, 2430, and 2440, which correspond to those described with reference to FIGS. 3 to 5.

In this case, the through electrode includes a first through electrode 2410 disposed in the first insulating layer 2110.

For example, the first insulating layer 2110 includes a first-first through electrode 2411 and a first-second through electrode 2412 spaced apart from each other in the horizontal direction.

In this case, the first-first through electrode 2411 may be disposed in a first region in the first insulating layer 2110, and the first-second through electrode 2412 may be disposed in a second region spaced apart from the first region in the first insulating layer 2110 in the horizontal direction.

Preferably, the first-first through electrode 2411 may be disposed in a region of the first insulating layer 2110 that vertically overlaps the chip 2700. Preferably, the first-first through electrode 2411 may be disposed in a region vertically overlapping the corner region of the chip 2700 among the entire region in the horizontal direction of the first insulating layer 2110.

The first-second through electrode 2412 may be disposed in a region that does not overlap the chip 2700 in the vertical direction among the entire regions in the horizontal direction of the first insulating layer 2110 while being spaced apart from the first-first through electrode 2411 in the horizontal direction.

In this case, the first-first through electrode 2411 and the first-second through electrode 2412 may have different widths.

In this case, each of the first-first through electrode 2411 and the first-second through electrode 2412 may have an hourglass shape. Accordingly, a width of the first-first through electrode 2411 and a width of the first-second through electrode 2412 described below may mean a width of a region having a greatest width among all regions in a thickness direction of a corresponding through electrode, a width of a region having a smallest width, and an average width of the entire region, respectively. The widths of the first-first through electrode 2411 and the second insulating layer 120 may be changed according to a design of the circuit board. However, in an embodiment, the width W1 of the first-first through electrode 2411 is greater than the width W2 of the first-second through electrode 2412.

Preferably, among the through electrodes disposed in the first insulating layer 2110 of the embodiment, the first-first through electrode 2411 disposed in a region vertically overlapping the chip 2700 may have a first width W1. And, among the through electrodes disposed in the first insulating layer 2110, the first-second through electrode 2412 disposed in the region that does not vertically overlapping the chip 2700 may have a second width W2 smaller than the first width W1.

For example, the first width W1 of the first-first through electrode 2411 may satisfy a range of 120% to 160% of the second width W2 of the first-second through electrode 2412. For example, the first width W1 of the first-first through electrode 2411 may satisfy a range of 125% to 155% of the second width W2 of the first-second through electrode 2412. For example, the first width W1 of the first-first through electrode 2411 may satisfy a range of 130% to 150% of the second width W2 of the first-second through electrode 2412.

In this case, if the first width W1 of the first-first through electrode 2411 is less than 120% of the second width W2 of the first-second through electrode 2412, the warpage improvement effect caused by the increase in the first width W1 of the first-first through electrode 2411 may be insufficient.

In addition, if the first width W1 of the first-first through electrode 2411 exceeds 160% of the second width W2 of the first-second through electrode 2412, processability in the process of plating the first-first through electrode 2411 may be deteriorated, and the degree of improvement of the warpage improvement effect may be insufficient compared to the increase in width. For example, if the first width W1 of the first-first through electrode 2411 exceeds 160% of the second width W2 of the first-second through electrode 2412, the size of the through hole formed in the first insulating layer 2110 correspondingly increases. At this time, if the size of the through hole increases, it is difficult to form a metal layer having a uniform thickness in the through hole, and accordingly, a flatness of the second-first electrode part 2310 connected to the first-first through electrode 2411 may be reduced (e.g., dimples may be provided at a surface). In addition, if the flatness of the second-first electrode 2310 decreases, the flatness of the second-first insulating layer 2121 disposed on the second-first electrode 2310 decreases, and accordingly, the flatness of the third insulating layer 2130 may decrease. And, when the flatness of the third insulating layer 2130 decreases, and accordingly, the mounting processability of the chip mounted on the first electrode part 2200 may be deteriorated.

Accordingly, the embodiment allows the first width W1 of the first-first through electrode 2411 to have a range between 120% and 160% of the second width W2 of the first-second through electrode 2412 to solve the reliability problem described above, and to improve the warpage characteristics in a region vertically overlapping with the chip 2700.

In this case, unlike the previous embodiment, the embodiment may improve warpage characteristics of the circuit board without including the reinforcement part in the circuit board. In this case, when the reinforcement part is included in the circuit board, the through electrode or the electrode part cannot be disposed in a region in which the reinforcement part is disposed. Accordingly, there may be a problem in that circuit integration is deteriorated according to the arrangement of the reinforcement part.

Alternatively, the embodiment increases the first width W1 of the first-first through electrode 2411 that overlaps the chip 2700 in a vertical direction among through electrodes disposed in the first insulating layer 2110 of the circuit board, and improves the warpage characteristics in the region overlapping the chip 2700 in the vertical direction. Accordingly, the embodiment may have a structure in which through electrodes are disposed in the region vertically overlapping the chip 2700. Accordingly, the embodiment may improve the warpage characteristics in the region overlapping the chip in the vertical direction without affecting the circuit integration.

On the other hand, referring to FIG. 10, in a second detailed structure, the warpage characteristics of the circuit board can be improved through a change in a size of the second through electrode 2420 disposed on the second insulating layer 2120 rather than the through electrode disposed on the first insulating layer 2110.

Specifically, a second through electrode 2420 is disposed on the second insulating layer 2120.

In this case, the second through electrode 2420 may be divided into a second-first through electrode 2421 and a second-second through electrode 2422 according to an arrangement region.

The second-first through electrode 2421 may be disposed in the second insulating layer 2120, and may overlap the chip 2700 in a vertical direction. For example, the second-first through electrode 2421 may be disposed in a region overlapping a corner region of the chip 2700 in a vertical direction among the entire region of the second insulating layer 2120 in the horizontal direction.

In addition, the second-second through electrode 2422 may be disposed in a region that is spaced apart from the second-first through electrode 2421 in the horizontal direction and does not overlap the chip 2700 in the vertical direction among the entire region of the second insulating layer 2120.

In addition, a third width W3 of the second-first through electrode 2421 may be different from a fourth width W4 of the second-second through electrode 2422.

Preferably, a third width W3 of the second-first through electrode 2421 disposed in the region overlapping the chip 2700 in the vertical direction may be greater than the fourth width W4 of the second-second through electrode 2422.

Specifically, the third width W3 of the second-first through electrode 2421 may satisfy a range of 120% to 160% of the fourth width W4 of the second-second through electrode 2422. Preferably, the third width W3 of the second-first through electrode 2421 may satisfy a range of 125% to 155% of the fourth width W4 of the second-second through electrode 2422. Preferably, the third width W3 of the second-first through electrode 2421 may satisfy a range of 130% to 150% of the fourth width W4 of the second-second through electrode 2422.

Accordingly, the embodiment may improve the warpage characteristics of the circuit board by increasing the third width W3 of the second-first through electrode 2421 vertically overlapping the chip 2700 with respect to the second through electrode 2420 disposed in the second insulating layer 2120 instead of the first insulating layer 2110. Thus, the embodiment may improve the warpage characteristics of the circuit board without including a material such as reinforcement part and without affecting the circuit integration of the circuit board. Preferably, the embodiment may improve the warpage characteristics in the region vertically overlapping the chip 2700 among the entire region of the circuit board. Accordingly, the embodiment may improve the physical and electrical reliability of the first electrode part 2200, and further improve the operational characteristics of the chip 2700 while improving the mounting processability of the chip 2700 mounted on the first electrode part 2200.

Meanwhile, in FIGS. 9 and 10, the warpage characteristic is improved by increasing the width of any one of the through electrodes disposed on the first insulating layer 2110 and the through electrode disposed on the second insulating layer 2120. However, the embodiment is not limited thereto, and the width of the through electrode disposed in the second insulating layer 2120 together with the through electrode disposed in the first insulating layer 2110 may be increased, thereby further improving the warpage characteristic.

Meanwhile, a third through electrode 2440 is disposed in the third insulating layer 2130. However, the third through electrode 2440 is connected to a first electrode part 2200 connected to the chip 2700. In this case, when a width of the third through electrode 2440 increases, circuit integration decreases accordingly, and all of the first electrode part 2200 connected to the chip 2700 may not be disposed within the limited space. Accordingly, the embodiment increases the width of at least one through electrode disposed in a region overlapping the chip 2700 in a vertical direction among through electrodes disposed in the first insulating layer 2110 and the second insulating layer 2120 except for the third through electrode 2440 disposed on the third insulating layer 2130.

Hereinafter, a fourth embodiment will be described.

Unlike the first and second embodiments, the fourth embodiment makes it possible to improve the warpage characteristics of the semiconductor package without including a reinforcement part.

In this case, the third embodiment improves the warpage characteristics of the semiconductor package by increasing the width of the through electrode overlapping the chip 2700 in the vertical direction among the through electrodes disposed in the first insulating layer 2110 and the second insulating layer 2120.

Alternatively, the fourth embodiment improves the warpage characteristics of the semiconductor package by increasing a thickness of an electrode part rather than the through electrode.

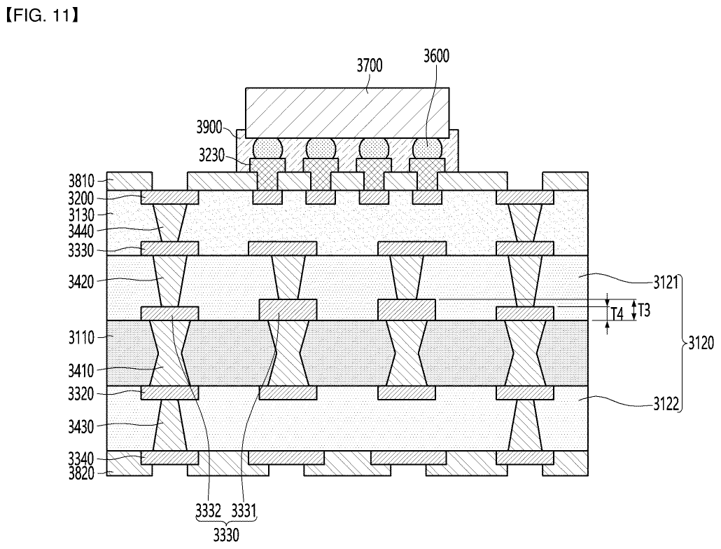

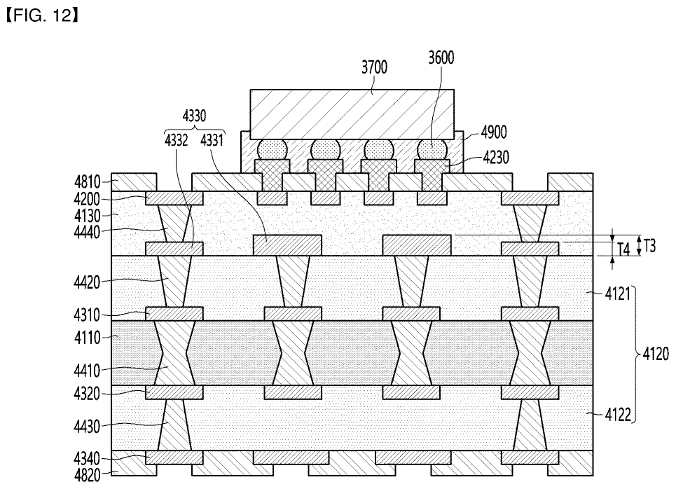

FIG. 11 is a diagram showing a first detailed structure of a semiconductor package according to a fourth embodiment, and FIG. 12 is a diagram showing a second detailed structure of a semiconductor package according to a fourth embodiment.

Referring to FIGS. 11 and 12, the fourth embodiment increases a thickness of an electrode part disposed on a surface of any one of the plurality of insulating layers.

In addition, if the thickness of the electrode part is increased, the warpage characteristic in the region where the thickness of the electrode part is increased may be improved compared to other structures. Through this, the embodiment improves the warpage characteristics of the semiconductor package without affecting the circuit integration of the semiconductor package through the thickness change of the electrode part.

Referring to FIG. 11, the semiconductor package may include a first insulating layer 3110, a second insulating layer 3120, 3211 and 3212, a third insulating layer 3130, a first electrode part 3200, a second electrode part 3310, 3320, 3330, 3340, and through electrodes 3410, 3420, 3430, and 3440, which correspond to those described with reference to FIGS. 3 to 5.

In this case, the second electrode part includes a second electrode part disposed on at least one surface of the first insulating layer 3110.

That is, the embodiment includes a second electrode part 3310 disposed on an upper surface of the first insulating layer 3110.

In this case, the second electrode part 3310 may include a plurality of second electrodes spaced apart from each other in the horizontal direction on the upper surface of the first insulating layer 3110.

For example, the second electrode part 3310 may include a second-first electrode part 3311 disposed in a first region of an upper surface of the first insulating layer 3110. Also, the second electrode part 3310 includes a second-second electrode part 3312 horizontally spaced apart from the second-first electrode part 3311 on the upper surface of the first insulating layer 3110.

For example, the second-first electrode part 3311 may be disposed in a region of the upper surface of the first insulating layer 3110 that overlaps the chip 3700 in the vertical direction. For example, at least a portion of the second-first electrode part 3311 may overlap a corner region of the chip 3700 of the upper surface of the first insulating layer 3110 in a vertical direction. In addition, the second-first electrode part 3311 may have a first thickness T1.

Meanwhile, the second-second electrode part 3312 may be disposed in a region of the upper surface of the first insulating layer 3110 that does not vertically overlap the chip 3700. In addition, the second-second electrode part 3312 may have a second thickness T2 different from the first thickness T1.

For example, the first thickness T1 of the second-first electrode part 3311 may be greater than the second thickness T2 of the second-second electrode part 3312. Preferably, the first thickness T1 of the second-first electrode part 3311 may satisfy a range of 120% to 160% of the second thickness T2 of the second-second electrode part 3312. For example, the first thickness T1 of the second-first electrode part 3311 may satisfy a range of 125% to 155% of the second thickness T2 of the second-second electrode part 3312. For example, the first thickness T1 of the second-first electrode part 3311 may satisfy a range of 130% to 150% of the second thickness T2 of the second-second electrode part 3312.

If the first thickness T1 of the second-first electrode part 3311 is less than 120% of the second thickness T2 of the second-second electrode part 3312, the effect of improving the warpage characteristics caused by the increase in the thickness of the second-first electrode part 3311 may be insufficient.

In addition, if the first thickness T1 of the second-first electrode part 3311 exceeds 160% of the second thickness T2 of the second-second electrode part 3312, the resistance of the second-first electrode part 3311 increases, and thus signal characteristics may deteriorate. In addition, if the first thickness T1 of the second-first electrode part 3311 exceeds 160% of the second thickness T2 of the second-second electrode part 3312, there is a height difference between a region vertically overlapping the second-first electrode part 3311 and a region vertically overlapping the second-second electrode part 3312 among an entire region of the second insulating layer 3120 disposed on the second electrode part 3310, and accordingly, the flatness of the circuit board and semiconductor package may be reduced.

Accordingly, the embodiment allows the first thickness T1 of the second-first electrode part 3311 to satisfy the range of 120% to 160% of the second thickness T2 of the second-second electrode part 3312, thereby improving the warpage characteristics in the region vertically overlapping with the second-first electrode part 3311.

Meanwhile, referring to FIG. 12, the semiconductor package may include a first insulating layer 4110, a second insulating layer 4120, 4211 and 4212, a third insulating layer 4130, a first electrode part 4200; a second electrode part 4310, 4320, 4330, 4340; and through electrodes 4410, 4420, 4430, and 4440.

In this case, the second electrode part includes a second electrode part disposed on at least one surface of the second insulating layer 4120. Hereinafter, a second insulating layer disposed on an upper surface of the first insulating layer 4110 among the second insulating layers will be mainly described.

That is, in an embodiment, a second electrode part 4330 may be formed on an upper surface of the second insulating layer 4121 disposed on the upper surface of the first insulating layer 4110.

For example, in this case, the second electrode part 4330 may include a plurality of second electrodes spaced apart from each other in a horizontal direction on the upper surface of the second insulating layer 4121.

For example, the second electrode part 4330 may include a second-first electrode part 4331 disposed in a first region of the upper surface of the second insulating layer 4121. Also, the second electrode part 4330 includes a second-second electrode part 432 spaced apart from the second-first electrode part 4331 in a horizontal direction on the upper surface of the second insulating layer 4121.

For example, the second-first electrode part 4331 may be disposed in a region vertically overlapping the chip 4700 on the upper surface of the second insulating layer 4121. For example, at least a portion of the second-first electrode part 4331 may vertically overlap a corner region of the chip 4700 on the upper surface of the second insulating layer 4121. In addition, the second-first electrode part 4331 may have a third thickness T3.

Meanwhile, the second-second electrode part 4332 may be disposed in a region of the upper surface of the second insulating layer 4121 that does not vertically overlap the chip 4700. In addition, the second-second electrode part 4332 may have a fourth thickness T4 different from the third thickness T3.

For example, the third thickness T3 of the second-first electrode part 4331 may be greater than the fourth thickness T4 of the second-second electrode part 4332. Preferably, the third thickness T3 of the second-first electrode part 4331 may satisfy a range of 120% to 160% of the fourth thickness T4 of the second-second electrode part 4332. For example, the third thickness T3 of the second-first electrode part 4331 may satisfy a range of 125% to 155% of the fourth thickness T4 of the second-second electrode part 4332. For example, the third thickness T3 of the second-first electrode part 4331 may satisfy a range of 130% to 150% of the fourth thickness T4 of the second-second electrode part 4332.

That is, an embodiment may improve warpage characteristics of a circuit board and a semiconductor package by increasing the thickness of at least one electrode part overlapping the chip in a vertical direction among the electrode part disposed on the surface of the first insulating layer and the electrode part disposed on the surface of the second insulating layer. Accordingly, the embodiment may improve the warpage characteristics of the circuit board and the semiconductor package without affecting the circuit integration of the circuit board and the semiconductor package, thereby improving the operation characteristics of the chip.

Furthermore, in FIGS. 11 and 12, the thickness of any one of the electrode part disposed on the surface of the first insulating layer and the electrode part disposed on the surface of the second insulating layer is changed, but the embodiment is not limited thereto.

For example, it is possible to increase the thickness of the electrode part vertically overlapping the chip among the electrode parts disposed on the upper surface of the first insulating layer, while increasing the thickness of the electrode part vertically overlapping the chip among the electrode parts disposed on the upper surface of the second insulating layer.

Meanwhile, the first electrode part 4200 disposed on the third insulating layer 4130 has an ultra-fine pattern and is connected to the chip 4700. In this case, when the thickness of the first electrode part 4200 increases, it is difficult to miniaturize the first electrode part, and thus, both the pad and the chip trace connected to the chip may not be disposed within the limited space. Accordingly, in an embodiment, when the thickness of the electrode part is increased, the thickness of any one of the second electrode parts disposed on the surfaces of the first insulating layer and the second insulating layer except for the first electrode part is increased.

Meanwhile, an embodiment may provide a circuit board and a semiconductor package in which the structure of the third embodiment is combined with the structure of the fourth embodiment.

For example, the embodiment may increase the width of any one of the through electrodes vertically overlapping the chip and increase the thickness of any one of the electrode parts vertically overlapping the chip.

In addition, the embodiment may be a combination of the structures of the first and second embodiments and the structures of the third and fourth embodiments.

In an embodiment, a reinforcement part is disposed in a region vertically overlapping the chip in any one of a plurality of insulating layers. In addition, the width of the through electrode or the thickness of the electrode part disposed in another one of the plurality of insulating layers may be increased.

The semiconductor package according to an embodiment may include an insulating layer, a first electrode part, and a chip. The semiconductor package may include a reinforcement part disposed in a region overlapping the chip in a vertical direction among an entire region of the insulating layer. The reinforcement part may function to improve rigidity in a region overlapping the chip the vertical direction. Accordingly, the embodiment may prevent a region overlapping the chip from being greatly bent in a specific direction. The embodiment may improve physical and electrical reliability of a mounting pad or chip trace of the first electrode part disposed in a region overlapping the chip in a vertical direction, and thus improve operation characteristics of the chip. Accordingly, an electronic product, a server, and/or the like to which the semiconductor package according to an embodiment is applied may operate stably.

In addition, when a plurality of chips are mounted on the semiconductor package, the reinforcement part may vertically overlap a region between the plurality of chips. Accordingly, the embodiment may prevent bending in a specific direction in a region between the plurality of chips. Accordingly, the embodiment may solve the problem of deteriorating the physical reliability of chip traces connecting the plurality of chips.

In addition, the embodiment may include a through electrode disposed in the circuit board. In this case, the through electrode may include a first through electrode disposed in a region overlapping the chip in a vertical direction and a second through electrode that does not overlap the chip in a vertical direction. Widths of the first through electrode and the second through electrode may be different from each other. For example, the first through electrode overlapping the chip in a vertical direction may be greater than the width of the second through electrode. Accordingly, an embodiment may improve warpage characteristics in a region overlapping the chip in a vertical direction by increasing a width of the first through electrode disposed in a region vertically overlapping the chip with respect to a width of the second through electrode. An embodiment may have a structure in which a through electrode is disposed in a region vertically overlapping the chip. Accordingly, an embodiment may improve warpage characteristics in a region overlapping the chip in a vertical direction without affecting circuit integration.

In addition, the embodiment may include a second electrode part spaced apart from the first electrode part in a thickness direction. The second electrode part may include a second-first electrode part that does not overlap a chip in a vertical direction and a second-second electrode part that does not overlap the chip in a vertical direction. The thickness of the second-first electrode part and the thickness of the second-second electrode part may be different from each other.

For example, a thickness of the second-first electrode part disposed in a region vertically overlapping the chip may be greater than a thickness of the second-second electrode part. The embodiment may improve warpage characteristics in the region vertically overlapping the chip by increasing the thickness of the second-first electrode part disposed in the region vertically overlapping the chip with respect to the thickness of the second-second electrode part. Accordingly, the embodiment may improve warpage characteristics in the region vertically overlapping the chip without affecting circuit integration.

Hereinafter, a method of manufacturing a semiconductor package according to an embodiment will be described in order of processes.

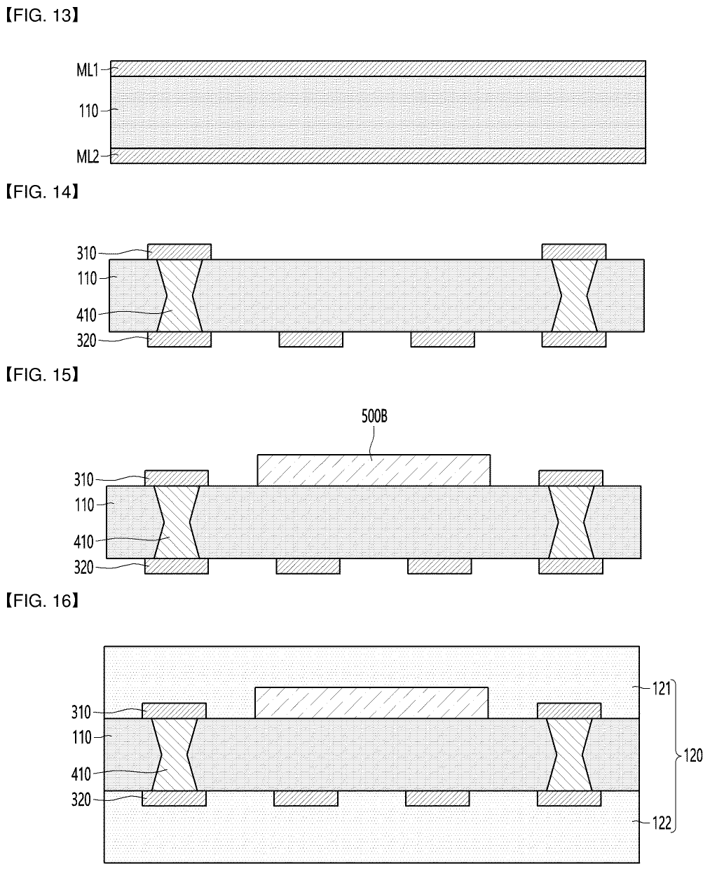

FIGS. 13 to 22 are diagrams showing a method of manufacturing the semiconductor package shown in FIG. 4 in order of processes. However, based on the manufacturing method described below, it may be possible to manufacture a semiconductor package of drawings other than FIG. 4.

Referring to FIG. 13, an embodiment prepares a base material for manufacturing a semiconductor package. For example, the base material may be a copper clad laminated (CCL). Accordingly, the base material includes a first insulating layer 110 corresponding to a core layer and copper foil layers ML1 and ML2 disposed on upper and lower surfaces of the first insulating layer 110. In this case, the manufacturing process described below may be performed after the copper foil layers ML1 and ML2 are removed, or may be performed in a state in which the copper foil layers ML1 and ML2 are present.

Next, referring to FIG. 14, in an embodiment, an electrode part and a through electrode may be formed on the first insulating layer 110 based on the base material. For example, the embodiment may proceed with a process of forming a through hole (not shown) penetrating the first insulating layer 110. Thereafter, the embodiment may proceed with a process of forming electrode parts 310 and 320 on the upper and lower surfaces of the first insulating layer 110 while forming the first through electrode 410 filling the through hole. In this case, in the embodiment, an electrode part may not be formed in a region of the upper surface of the first insulating layer 110 vertically overlapping the first region. In addition, a through electrode may not be disposed in a region of the first insulating layer 110 vertically overlapping the first region.

Next, referring to FIG. 15, the embodiment may proceed with a process of disposing a reinforcement part 500B on the first region of the upper surface of the first insulating layer 110. In this case, the reinforcement part 550B may include a separate adhesive member, and may be attached to the upper surface of the first insulating layer 110 through the adhesive member (not shown).

Next, referring to FIG. 16, the embodiment may proceed with a process of stacking the second insulating layer 120 on the first insulating layer 110. For example, the embodiment may proceed with a process of forming the second-first insulating layer 121 covering the reinforcement part 500B on the upper surface of the first insulating layer 110 and forming the second-second insulating layer 122 on a lower surface of the first insulating layer 110.

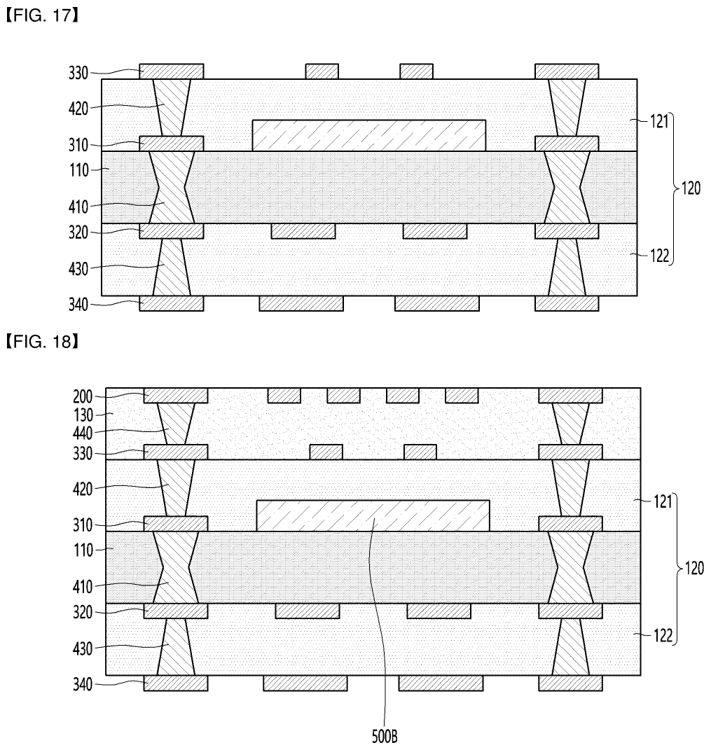

Next, referring to FIG. 17, an embodiment may proceed with a process of forming a through electrode and an electrode part on the second insulating layer 120, respectively. For example, an embodiment may proceed with a process of forming a through electrode 420 and an electrode part 330 on the second-first insulating layer 121. In this case, the through electrode 420 formed on the second-first insulating layer 121 may not overlap the reinforcement part 500B in a vertical direction. For example, the through electrode 420 formed in the second-first insulating layer 121 may be formed by avoiding a region in which the reinforcement part 500B is disposed among the entire regions of the second-first insulating layer 121. Accordingly, the through electrode 420 formed in the second-first insulating layer 121 is not connected to the reinforcement part 500B, and thus may be electrically insulated. Next, the embodiment may proceed with a process of forming a through electrode 430 and an electrode part 340 on the second-second insulating layer 122.

Next, referring to FIG. 18, the embodiment may proceed with a process of stacking the third insulating layer 130 on the second insulating layer 120. In this case, the third insulating layer 130 may include a photosensitive material. Accordingly, an embodiment may miniaturize an electrode part and a through electrode disposed on the third insulating layer 130. Thereafter, an embodiment forms a through electrode 440 and a first electrode part 200 on the third insulating layer 130.

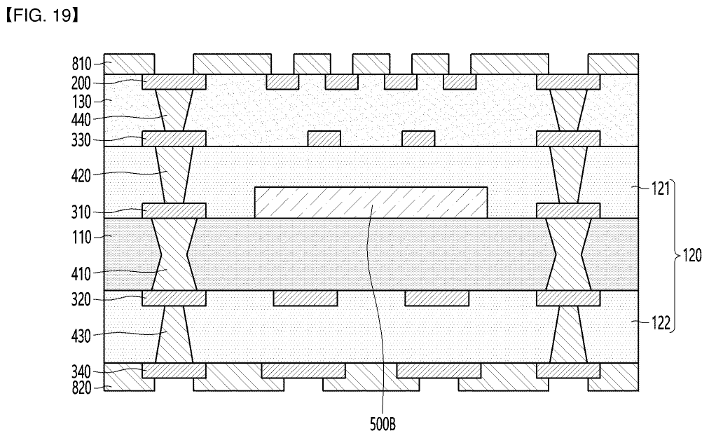

Next, referring to FIG. 19, an embodiment may proceed with a process of forming a first protective layer 810 including an opening (not shown) on the third insulating layer 130. Further, an embodiment may proceed with a process of forming a second protective layer 820 including an opening on a lower surface of the second-second insulating layer 122 disposed at a lowermost side of the second insulating layer 120.

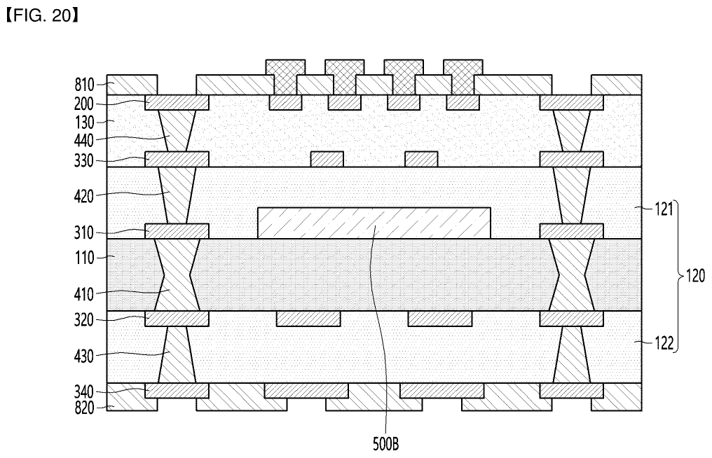

Next, referring to FIG. 20, the embodiment may proceed with a process of forming a bump 230 on at least a portion of the first electrode part 200. The bump 230 may penetrate the first protective layer 810.

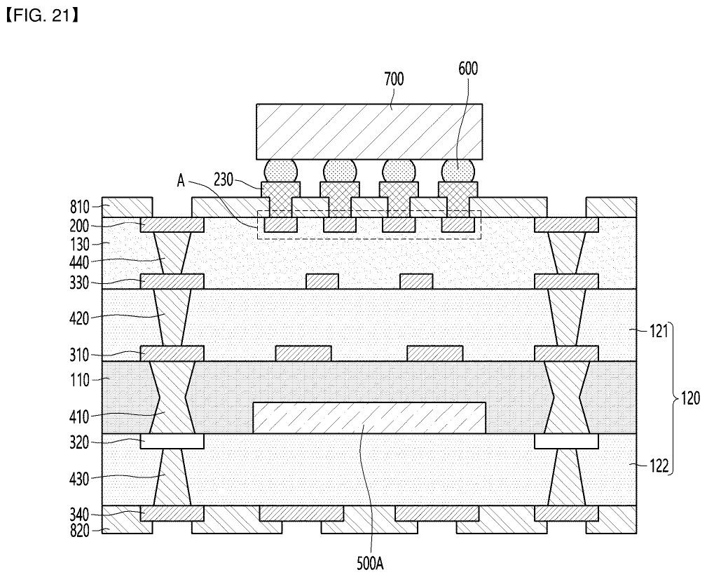

Next, referring to FIG. 21, the embodiment may proceed with a process of disposing the connection part 600 on the bump 230. In addition, the embodiment may proceed with a process of mounting the chip 700 on the connection part 600. Although it is shown that one chip is mounted in the drawing, it may have a structure in which at least two chips are mounted.

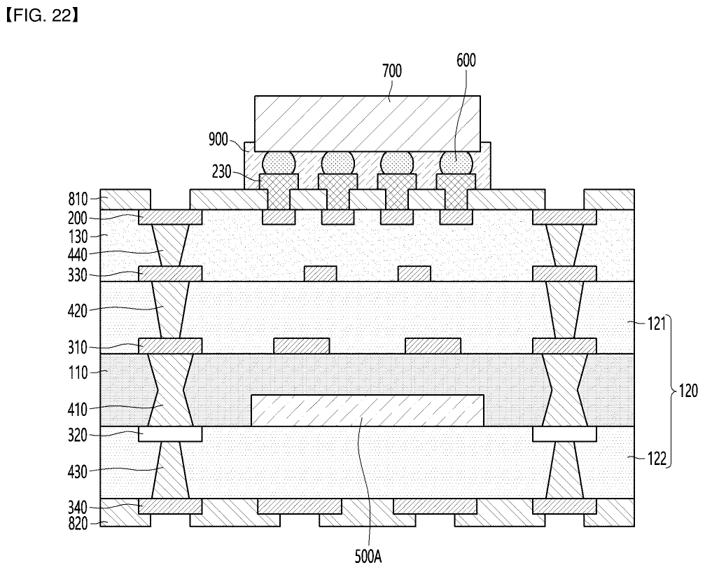

Next, referring to FIG. 22, the embodiment may proceed with a process of forming a fillet layer 900 for molding the lower region of the chip 700.

The semiconductor package according to an embodiment may include an insulating layer, a first electrode part, and a chip. The semiconductor package may include a reinforcement part disposed in a region overlapping the chip in a vertical direction among an entire region of the insulating layer. The reinforcement part may function to improve rigidity in a region overlapping the chip the vertical direction. Accordingly, the embodiment may prevent a region overlapping the chip from being greatly bent in a specific direction. The embodiment may improve physical and electrical reliability of a mounting pad or chip trace of the first electrode part disposed in a region overlapping the chip in a vertical direction, and thus improve operation characteristics of the chip. Accordingly, an electronic product, a server, and/or the like to which the semiconductor package according to an embodiment is applied may operate stably.

In addition, when a plurality of chips are mounted on the semiconductor package, the reinforcement part may vertically overlap a region between the plurality of chips. Accordingly, the embodiment may prevent bending in a specific direction in a region between the plurality of chips. Accordingly, the embodiment may solve the problem of deteriorating the physical reliability of chip traces connecting the plurality of chips.

In addition, the embodiment may include a through electrode disposed in the circuit board. In this case, the through electrode may include a first through electrode disposed in a region overlapping the chip in a vertical direction and a second through electrode that does not overlap the chip in a vertical direction. Widths of the first through electrode and the second through electrode may be different from each other. For example, the first through electrode overlapping the chip in a vertical direction may be greater than the width of the second through electrode. Accordingly, an embodiment may improve warpage characteristics in a region overlapping the chip in a vertical direction by increasing a width of the first through electrode disposed in a region vertically overlapping the chip with respect to a width of the second through electrode. An embodiment may have a structure in which a through electrode is disposed in a region vertically overlapping the chip. Accordingly, an embodiment may improve warpage characteristics in a region overlapping the chip in a vertical direction without affecting circuit integration.

In addition, the embodiment may include a second electrode part spaced apart from the first electrode part in a thickness direction. The second electrode part may include a second-first electrode part that does not overlap a chip in a vertical direction and a second-second electrode part that does not overlap the chip in a vertical direction. The thickness of the second-first electrode part and the thickness of the second-second electrode part may be different from each other.

For example, a thickness of the second-first electrode part disposed in a region vertically overlapping the chip may be greater than a thickness of the second-second electrode part. The embodiment may improve warpage characteristics in the region vertically overlapping the chip by increasing the thickness of the second-first electrode part disposed in the region vertically overlapping the chip with respect to the thickness of the second-second electrode part. Accordingly, the embodiment may improve warpage characteristics in the region vertically overlapping the chip without affecting circuit integration.

On the other hand, when the circuit board having the above-described characteristics of the invention is used in an IT device or home appliance such as a smart phone, a server computer, a TV, and the like, functions such as signal transmission or power supply can be stably performed. For example, when the circuit board having the features of the present invention performs a semiconductor package function, it can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other. Furthermore, when the circuit board having the above-described characteristics of the invention is used in a transportation device such as a vehicle, it is possible to transmit a high-current signal required by the vehicle at a high speed, thereby improving the safety of the transportation device. Furthermore, the circuit board and the semiconductor package including the same can be operated normally even in an unexpected situation occurring in various driving environments of the transportation device, thereby safely protecting the driver.

Features, structures, effects, etc. described in the above embodiments are included in at least one embodiment, and it is not necessarily limited to only one embodiment. Furthermore, features, structures, effects, etc. illustrated in each embodiment can be combined or modified for other embodiments by those of ordinary skill in the art to which the embodiments belong. Accordingly, the contents related to such combinations and variations should be interpreted as being included in the scope of the embodiments.

In the above, the embodiment has been mainly described, but this is only an example and does not limit the embodiment, and those of ordinary skill in the art to which the embodiment pertains will appreciate that various modifications and applications not illustrated above are possible without departing from the essential characteristics of the present embodiment. For example, each component specifically shown in the embodiment can be implemented by modification. And the differences related to these modifications and applications should be interpreted as being included in the scope of the embodiments set forth in the appended claims.

1. A semiconductor package comprising:
an insulating layer;
a first electrode part disposed on the insulating layer;
a through electrode passing through the insulating layer and electrically connected to the first electrode part; and
a reinforcement part disposed in the insulating layer;
a connection part disposed on the first electrode part; and
a chip mounted on the connection part,
wherein at least a portion of the reinforcement part vertically overlaps the chip and is not connected to the through electrode.

2. The semiconductor package of claim 1, wherein a thickness of the reinforcement part is greater than a thickness of the first electrode part.

3. The semiconductor package of claim 1, wherein the reinforcement part vertically overlaps a corner region of the chip.

4. The semiconductor package of claim 1, wherein the insulating layer includes a plurality of insulating layers including different insulating materials, and
wherein the reinforcement part is disposed in at least one of the plurality of insulating layers to overlap the chip in a vertical direction.

5. The semiconductor package of claim 4, wherein the plurality of insulating layers comprise:
a first insulating layer provided with a first insulating material,
a second insulating layer disposed on the first insulating layer and including a second insulating material different from the first insulating material, and
a third insulating layer disposed on the second insulating layer and including a third insulating material different from the first and second insulating materials,
wherein the reinforcement part is disposed in at least one of the first to third insulating layers.

6. The semiconductor package of claim 5, wherein the chip includes a first chip and a second chip spaced apart from the first chip in a horizontal direction, and
wherein the reinforcement part includes:
a first reinforcement part vertically overlaps the first chip,
a second reinforcement part vertically overlaps the second chip, and
a third reinforcement part vertically overlapping a region between the first and second chips.

7. The semiconductor package of claim 5, wherein the through electrode includes a first through electrode passing through at least one of the first and second insulating layers,
wherein the first through electrode includes first-first through electrode and first-second through electrode spaced apart from each other in a horizontal direction, and
wherein a width of the first-first through electrode is different from that of the first-second through electrode.

8. The semiconductor package of claim 7, wherein the first-first through electrode overlaps the chip in a vertical direction,
wherein the first-second through electrode does not overlap the chip in the vertical direction, and
wherein a width of the first-first through electrode is greater than that of the first-second through electrode.

9. The semiconductor package of claim 5, further comprising:
a second electrode part disposed on at least one of the first insulating layer and the second insulating layer,
wherein the second electrode part includes a second-first electrode part and a second-second electrode part spaced apart from each other in a horizontal direction, and
wherein a thickness of the second-first electrode part is different from that of the second-second electrode part.

10. The semiconductor package of claim 9, wherein the second-first electrode part overlaps the chip in a vertical direction,
wherein the second-second electrode part does not overlap the chip in the vertical direction, and
wherein the thickness of the second-first electrode part is greater than that of the second-second electrode part.
